(19) United States
(12) Patent Application Publication
(10) Pub. No.: US 2024/0429296 A1
(43) Pub. Date: Dec. 26, 2024

(54) NITRIDE SEMICONDUCTOR DEVICE

(71) Applicant: ROHM CO., LTD., Kyoto-shi (JP)

(72) Inventors: Shinya TAKADO, Kyoto-shi (JP); Hirotaka OTAKE, Kyoto-shi (JP)

(73) Assignee: ROHM CO., LTD., Kyoto-shi (JP)

(21) Appl. No.: 18/827,145

(22) Filed: Sep. 6, 2024

Related U.S. Application Data
(63) Continuation of application No. PCT/JP2023/006954, filed on Feb. 27, 2023.

(30) Foreign Application Priority Data
Mar. 10, 2022 (JP) 2022-037326

(51) Int. Cl. H01L 29/423; H01L 29/417; H01L 29/778

(52) U.S. Cl. CPC H01L 29/42376; H01L 29/41775; H01L 29/4238; H01L 29/778

(57) ABSTRACT

A nitride semiconductor device includes: an electron supply layer; a gate layer, a gate electrode; a passivation layer; a source electrode; a drain electrode; an active region; and an inactive region that is adjacent to the active region in a second direction orthogonal to a first direction in plan view. The gate layer includes a main gate part extending in the second direction in the active region, a subgate part extending in the second direction to be continuous with the main gate part in the inactive region, and a protruding part protruding from the subgate part toward a drain opening in the first direction.

### CROSS-REFERENCE TO RELATED APPLICATIONS

This application is a continuation of, and claims the benefit of priority from International Application No. PCT/JP2023/006954, filed on Feb. 27, 2023, which claims the benefit of priority from Japanese Patent Application No. 2022-037326, filed on Mar. 10, 2022, the entire contents of each of which are incorporated herein by reference.

### BACKGROUND

The present disclosure relates to a nitride semiconductor device.

Currently, a high electron mobility transistor (HEMT) using a nitride semiconductor has been commercialized (for example, refer to Japanese Laid-Open Patent Publication No. 2017-73506).

### BRIEF DESCRIPTION OF DRAWINGS

FIG. 1 is a schematic cross-sectional view of an exemplary nitride semiconductor device according to a first embodiment.

FIG. 2 is a schematic plan view showing an exemplary formation pattern of the nitride semiconductor device in FIG. 1.

FIG. 3 is an enlarged view of a part of the nitride semiconductor device in FIG. 2.

FIG. 4 is an enlarged view of a part of the nitride semiconductor device in FIG. 3.

FIG. 5 is an enlarged view of a part of the nitride semiconductor device in FIG. 3.

FIG. 6 is an enlarged view of a part of the nitride semiconductor device in FIG. 3.

FIG. 7 is an enlarged view of a part of the nitride semiconductor device in FIG. 3.

FIG. 8 is a schematic cross-sectional view taken along line F8-F8 of the nitride semiconductor device in FIG. 7.

FIG. 9 is a schematic cross-sectional view of an exemplary nitride semiconductor device according to a second embodiment.

FIG. 10 is a schematic plan view showing an exemplary formation pattern of the nitride semiconductor device in FIG. 9.

FIG. 11 is an enlarged view of a part of the nitride semiconductor device in FIG. 10.

FIG. 12 is a schematic plan view showing a formation pattern of an exemplary nitride semiconductor device according to a modified example.

FIG. 13 is a schematic plan view showing a part of a formation pattern of an exemplary nitride semiconductor device according to a modified example in an enlarged manner.

FIG. 14 is a schematic plan view showing a part of a formation pattern of an exemplary nitride semiconductor device according to a modified example in an enlarged manner.

FIG. 15 is a schematic plan view showing a formation pattern of an exemplary nitride semiconductor device according to a modified example.

FIG. 16 is a schematic plan view showing a part of a formation pattern of an exemplary nitride semiconductor device according to a modified example in an enlarged manner.

FIG. 17 is a schematic plan view showing a formation pattern of an exemplary nitride semiconductor device according to a modified example.

FIG. 18 is a schematic plan view showing a formation pattern of an exemplary nitride semiconductor device according to a modified example.

### DETAILED DESCRIPTION

Hereinafter, some embodiments of a nitride semiconductor device in the present disclosure will be described with reference to the accompanying drawings.

For simplicity and clarity of description, the components shown in the drawings are not necessarily drawn to scale. In addition, for easy understanding, hatching lines may be omitted in cross-sectional views. The accompanying drawings illustrate only embodiments of the present disclosure and should not be considered as limiting the present disclosure.

The following detailed description includes apparatus, systems, and methods embodying exemplary embodiments of the present disclosure. This detailed description is intended to be illustrative only and is not intended to limit the embodiments of the present disclosure or the application and use of such embodiments.

### First Embodiment

### Cross-Sectional Structure of Nitride Semiconductor Device

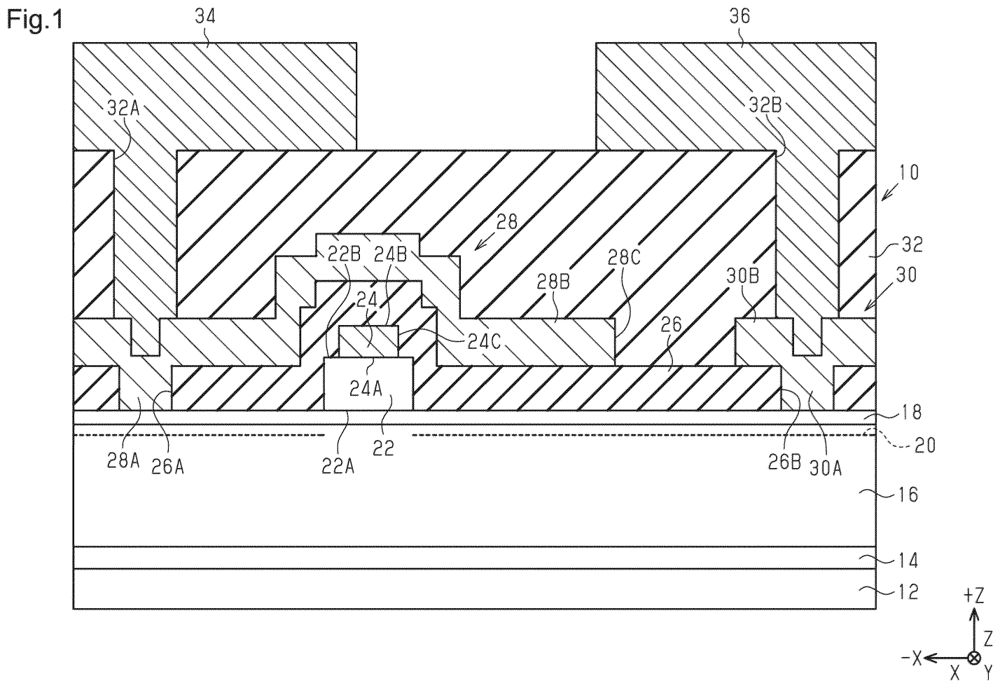

FIG. 1 is a schematic cross-sectional view of an exemplary nitride semiconductor device 10 according to a first embodiment. The term “plan view” used in the present disclosure refers to viewing the nitride semiconductor device 10 in the Z-axis direction of XYZ axes orthogonal to each other illustrated in FIG. 1. In addition, in the nitride semiconductor device 10 shown in FIG. 1, for the sake of convenience, the +Z direction is defined as an upward direction, the −Z direction is defined as a downward direction, the +X direction is defined as a rightward direction, and the −X direction is defined as a leftward direction. Unless explicitly stated otherwise, “plan view” refers to viewing the nitride semiconductor device 10 from above along the Z-axis.

The nitride semiconductor device 10 is a high electron mobility transistor (HEMT) using a nitride semiconductor. The nitride semiconductor device 10 includes a substrate 12, a buffer layer 14 formed on the substrate 12, an electron transit layer 16 formed on the buffer layer 14, and an electron supply layer 18 formed on the electron transit layer 16.

As the substrate 12, for example, a silicon (Si) substrate may be used. Alternatively, a silicon carbide (SiC) substrate, a gallium nitride (GaN) substrate, or a sapphire substrate may be used instead of the Si substrate. The thickness of the substrate 12 may be set to, for example, 200 μm or more and 1500 μm or less. In the following description, unless explicitly stated otherwise, the thickness refers to a dimension in the Z direction in FIG. 1.

The buffer layer 14 may be formed of any material capable of reducing lattice mismatch between the substrate 12 and the electron transit layer 16. In addition, the buffer layer 14 can include one or a plurality of nitride semiconductor layers. The buffer layer 14 may include, for example, at least one of an aluminum nitride (AlN) layer, an aluminum gallium nitride (AlGaN) layer, and a graded AlGaN layer having different aluminum (Al) compositions. For example, the buffer layer 14 may be formed of a single film of AlN, a single film of AlGaN, a film having an AlGaN/GaN superlattice structure, a film having an AlN/AlGaN superlattice structure, a film having an AlN/GaN superlattice structure, or the like.

In one example, the buffer layer 14 can include a first buffer layer that is an AlN layer formed on the substrate 12, and a second buffer layer that is an AlGaN layer formed on the AlN layer (first buffer layer). The first buffer layer may be, for example, an AlN layer having a thickness of 200 nm, and the second buffer layer may be, for example, a graded AlGaN layer having a thickness of 300 nm. In order to limit the leakage current in the buffer layer 14, impurities may be added to a part of the buffer layer 14 to cause a region other than the surface layer region of the buffer layer 14 to be semi-insulating. In this case, the impurity is, for example, carbon (C) or iron (Fe). The impurity concentration may be set to, for example, 4×10¹⁶ cm⁻³ or greater.

The electron transit layer 16 includes a nitride semiconductor. The electron transit layer 16 may be, for example, a GaN layer. The thickness of the electron transit layer 16 may be set to, for example, 0.5 μm or greater and 2 μm or less. In order to limit the leakage current in the electron transit layer 16, impurities may be added into a part of the electron transit layer 16 to cause a region other than the surface layer region of the electron transit layer 16 to be semi-insulating. In this case, the impurity is, for example, C. The impurity concentration may be set to, for example, 4×10¹⁶ cm⁻³ or greater. That is, the electron transit layer 16 can include a plurality of GaN layers having different impurity concentrations, in one example, a C-doped GaN layer and a non-doped GaN layer. In this case, the C-doped GaN layer is formed on the buffer layer 14. The C-doped GaN layer can have a thickness of 0.5 μm or greater and 2 μm or less. The concentration of carbon in the C-doped GaN layer may be set to 5×10¹⁷ cm⁻³ or greater and 9×10¹⁹ cm⁻³ or less. The non-doped GaN layer is formed on the C-doped GaN layer. The non-doped GaN layer can have a thickness of 0.05 μm or more and 0.4 μm or less. The non-doped GaN layer is in contact with the electron supply layer 18. In one example, electron transit layer 16 includes a C-doped GaN layer having a thickness of 0.9 μm and a non-doped GaN layer having a thickness of 0.1 μm. The concentration of carbon in the C-doped GaN layer is about 1×10¹⁸ cm⁻³.

The electron supply layer 18 includes a nitride semiconductor having a band gap larger than that of the electron transit layer 16. The electron supply layer 18 may be, for example, an AlGaN layer. In the nitride semiconductor, the band gap becomes larger, as the Al composition is increased. Therefore, the electron supply layer 18 which is an AlGaN layer has a larger band gap than the electron transit layer 16 which is a GaN layer. In one example, the electron supply layer 18 is formed of AlₓGa₁₋ₓN. That is, the electron supply layer 18 may be said to be an AlₓGa₁₋ₓN layer. x is 0<x<0.4, more preferably 0.1<x<0.3. The electron supply layer 18 can have a thickness of, for example, 5 nm or more and 20 nm or less.

The electron transit layer 16 and the electron supply layer 18 have different lattice constants in the bulk region. Therefore, the electron transit layer 16 and the electron supply layer 18 are bonded in a lattice mismatch system. Due to the spontaneous polarization of the electron transit layer 16 and the electron supply layer 18 and the piezoelectric polarization caused by the compressive stress applied to the heterojunction portion of the electron transit layer 16, the energy level of the conduction band of the electron transit layer 16 in the vicinity of the heterojunction interface between the electron transit layer 16 and the electron supply layer 18 becomes lower than the Fermi level. As a result, a two-dimensional electron gas (2DEG) 20 spreads in the electron transit layer 16 at a position close to the heterojunction interface between the electron transit layer 16 and the electron supply layer 18 (for example, a distance of about several nm from the interface).

The nitride semiconductor device 10 further includes a gate layer 22 formed on the electron supply layer 18 and a gate electrode 24 formed on the gate layer 22.

The gate layer 22 is formed on the electron supply layer 18. The gate layer 22 has a band gap smaller than that of the electron supply layer 18 and includes a nitride semiconductor having an acceptor impurity. The gate layer 22 may be formed of any material having a smaller band gap than, for example, the electron supply layer 18 which is an AlGaN layer. In one example, the gate layer 22 is a GaN layer (p-type GaN layer) doped with an acceptor impurity. The acceptor impurity can include at least one of zinc (Zn), magnesium (Mg), and C. The maximum concentration of the acceptor impurity in the gate layer 22 is, for example, 1×10¹⁸ cm⁻³ or more and 1×10²⁰ cm⁻³ or less.

As described above, the gate layer 22 includes an acceptor impurity, and thus the energy levels of the electron transit layer 16 and the electron supply layer 18 are raised. Therefore, in the region immediately below the gate layer 22, the energy level of the conduction band of the electron transit layer 16 in the vicinity of the heterojunction interface between the electron transit layer 16 and the electron supply layer 18 is substantially the same as or larger than the Fermi level. Therefore, when no gate voltage is applied to the gate electrode 24, that is, in the zero bias state, the 2DEG20 is not formed in the electron transit layer 16 in the region immediately below the gate layer 22. On the other hand, the 2DEG20 is formed in the electron transit layer 16 in a region other than the region immediately below the gate layer 22.

As described above, the 2DEG20 is depleted in the region immediately below the gate layer 22 due to the presence of the gate layer 22 doped with the acceptor impurity. As a result, the normally-off operation of the nitride semiconductor device 10 is achieved. When an appropriate on-voltage is applied to the gate electrode 24, a channel by the 2DEG20 is formed in the electron transit layer 16 in the region immediately below the gate electrode 24, and thus the source-drain conduction occurs.

The gate layer 22 includes a bottom surface 22A in contact with the electron supply layer 18 and an upper surface 22B opposite to the bottom surface 22A. The gate electrode 24 is formed on the upper surface 22B of the gate layer 22. The gate layer 22 may have a rectangular, trapezoidal, or ridge-shaped cross section in the ZX plane in FIG. 1.

The gate electrode 24 includes a bottom surface 24A in contact with the gate layer 22, an upper surface 24B opposite to the bottom surface 24A, and a side surface 24C extending between the bottom surface 24A and the upper surface 24B. The gate electrode 24 includes one or a plurality of metal layers. The gate electrode 24 is, for example, a titanium nitride (TiN) layer. Alternatively, the gate electrode 24 may include a first metal layer formed of a material including Ti and a second metal layer laminated on the first metal layer and formed of a material including TIN. The thickness of the gate electrode 24 may be, for example, 50 nm or more and 200 nm or less. The gate electrode 24 can form a Schottky junction with the gate layer 22.

The nitride semiconductor device 10 further includes a passivation layer 26, a source electrode 28, and a drain electrode 30.

The passivation layer 26 covers the electron supply layer 18, the gate layer 22, and the gate electrode 24, and has a source opening 26A and a drain opening 26B. Each of the source opening 26A and the drain opening 26B is separated from the gate layer 22. The gate layer 22 is located between the source opening 26A and the drain opening 26B. In FIG. 1, the source electrode 28 is in contact with the electron supply layer 18 via the source opening 26A. The drain electrode 30 is in contact with the electron supply layer 18 via the drain opening 26B. The passivation layer 26 may include a material having, for example, any one of silicon nitride (SiN), silicon dioxide (SiO₂), silicon oxynitride (SiON), alumina (Al₂O₃), AlN, and aluminum oxynitride (AlON). In one example, the passivation layer 26 is formed of a material including SiN.

The source electrode 28 and the drain electrode 30 include one or a plurality of metal layers (for example, Ti, Al, AlCu, TiN, or the like). The source electrode 28 and drain electrode 30 are in ohmic contact with 2DEG20 via the source opening 26A and drain opening 26B, respectively.

The source electrode 28 includes a source contact portion 28A and a source field plate portion 28B continuous with the source contact portion 28A. The source contact portion 28A corresponds to a portion filling the source opening 26A. The source field plate portion 28B is formed integrally with the source contact portion 28A. The source field plate portion 28B covers the passivation layer 26. The source field plate portion 28B includes an end portion 28C located between the drain opening 26B and the gate layer 22 in plan view. Therefore, the source field plate portion 28B is separated from the drain electrode 30 formed in the drain opening 26B. The source field plate portion 28B extends from the source contact portion 28A to the end portion 28C toward the drain electrode 30 along the surface of the passivation layer 26. The passivation layer 26 covers the upper surface of the electron supply layer 18, the side surface and the upper surface 22B of the gate layer 22, and the side surface 24C and the upper surface 24B of the gate electrode 24. Therefore, the source field plate portion 28B extending along the surface of the passivation layer 26 has a non-flat surface. The source field plate portion 28B plays a role of reducing electric field concentration in the vicinity of the end portion of the gate electrode 24 in the zero bias state, in which no gate voltage is applied to the gate electrode 24.

The drain electrode 30 includes a drain contact portion 30A and a drain plate portion 30B continuous with the drain contact portion 30A. The drain contact portion 30A corresponds to a portion filling the drain opening 26B. The drain plate portion 30B is formed integrally with the drain contact portion 30A. The drain plate portion 30B covers the passivation layer 26. The drain plate portion 30B is formed on the peripheral edge of the drain opening 26B in the passivation layer 26.

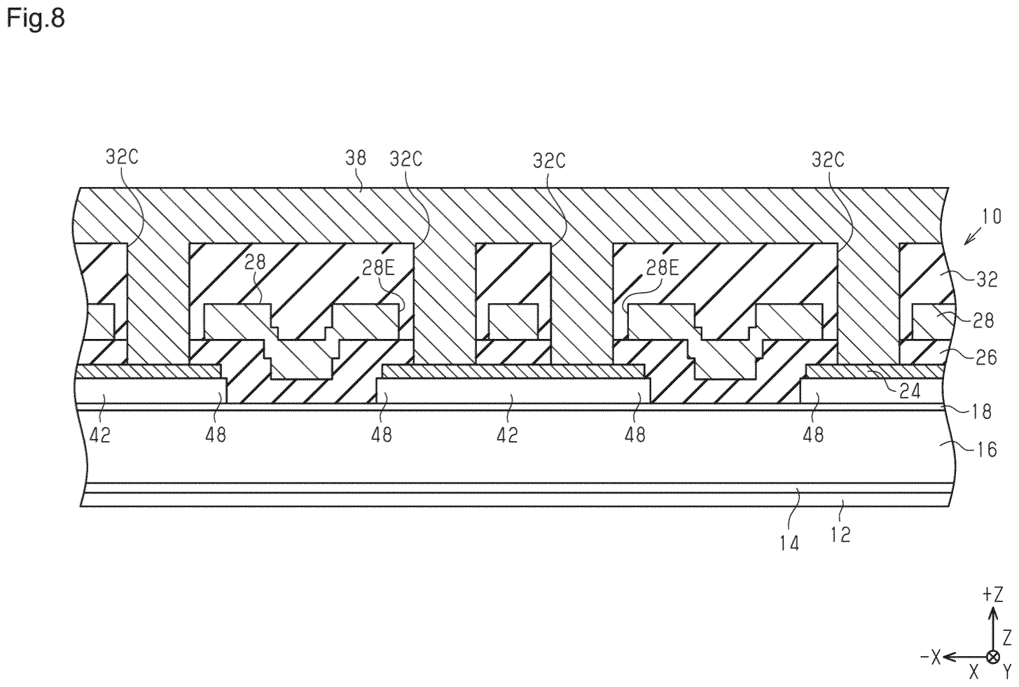

The nitride semiconductor device 10 further includes an interlayer insulating layer 32, a source wiring 34, a drain wiring 36, and a gate wiring 38 (refer to FIG. 8).

The interlayer insulating layer 32 covers the source electrode 28 and the drain electrode 30, and has a source wiring opening 32A and a drain wiring opening 32B. The source wiring opening 32A exposes the source electrode 28 from the interlayer insulating layer 32. The drain wiring opening 32B exposes the drain electrode 30 from the interlayer insulating layer 32. The interlayer insulating layer 32 may include, for example, a material containing any one of SiN, SiO₂, SiON, Al₂O₃, AlN, and AlON. In one example, the interlayer insulating layer 32 is formed of a material containing SiO₂.

A gate wiring opening 32C (refer to FIG. 8) is formed in the interlayer insulating layer 32 and the passivation layer 26. In the gate wiring opening 32C, the gate electrode 24 is exposed from both the interlayer insulating layer 32 and the passivation layer 26. The gate wiring opening 32C corresponds to a “gate opening”.

A source wiring 34, a drain wiring 36, and gate wiring 38 (refer to FIG. 8) are formed on the interlayer insulating layer 32 so as to be separated from each other. The source wiring 34 is in contact with the source electrode 28 via the source wiring opening 32A. The drain wiring 36 is in contact with the drain electrode 30 via the drain wiring opening 32B. The gate wiring 38 is in contact with the gate electrode 24 via the gate wiring opening 32C.

Each of the source wiring 34, the drain wiring 36, and the gate wiring 38 includes one or a plurality of metal layers. The metal layer may include a material having, for example, any one of copper (Cu), Al, Ti, and TiN. In one example, each of the source wiring 34, the drain wiring 36, and the gate wiring 38 is formed of a stacked structure of Ti, TiN, AlCu, and TiN.

### Overall Planar Structure of Nitride Semiconductor Device

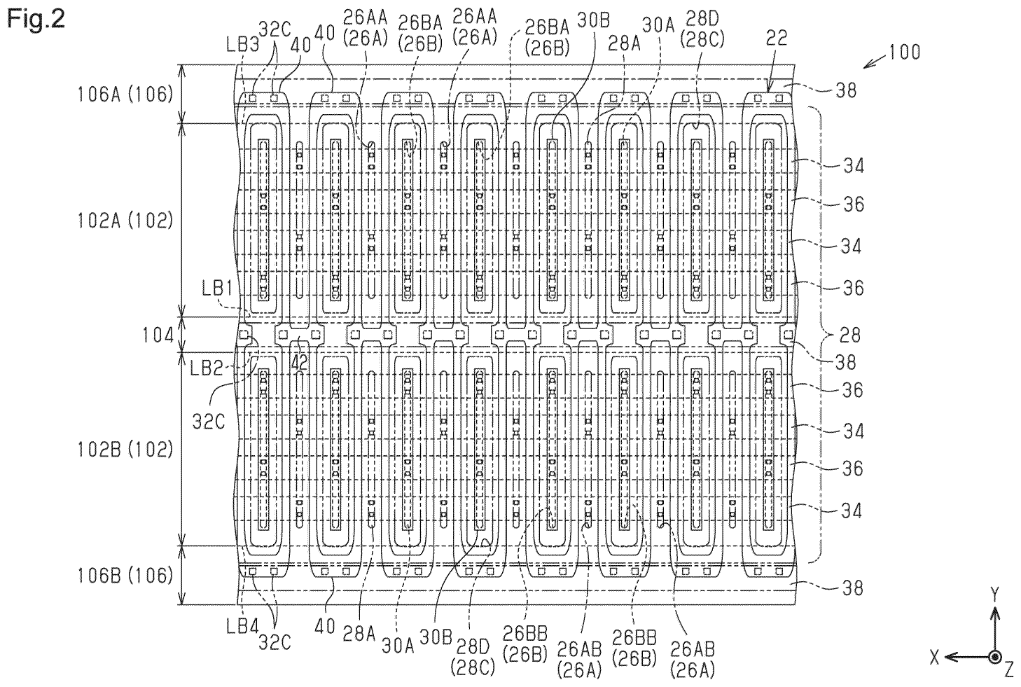

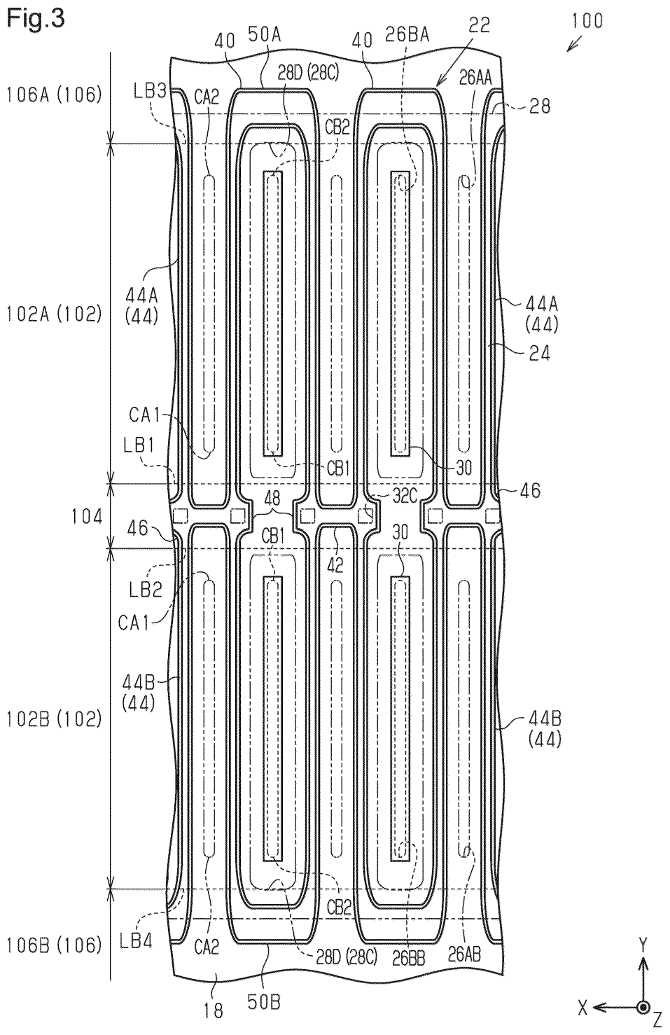

FIG. 2 is a schematic plan view showing an exemplary formation pattern 100 of the nitride semiconductor device 10 in FIG. 1. FIGS. 3 to 6 are enlarged views of a part of the formation pattern 100 of FIG. 2. In order to facilitate understanding, in FIGS. 2 to 6, components similar to those in FIG. 1 are denoted by the same reference numerals. The passivation layer 26, the source electrode 28, and the interlayer insulating layer 32 are transparently shown so that the gate layer 22 is shown. A part of the source electrode 28 is indicated by double-dashed lines. For the interlayer insulating layer 32, only the source wiring opening 32A, the drain wiring opening 32B, and the gate wiring opening 32C are indicated by broken lines. In FIG. 2, the source wiring 34, the drain wiring 36, and the gate wiring 38 are indicated by double-dashed lines. In FIG. 2, the gate electrode 24 is omitted for convenience.

As illustrated in FIG. 2, a plurality of source openings 26A and a plurality of drain openings 26B are formed in the passivation layer 26 (refer to FIG. 1). The plurality of source openings 26A and the plurality of drain openings 26B are alternately formed one by one in the X-axis direction. The source opening 26A and the drain opening 26B adjacent to each other in the X-axis direction are separated from each other in the X-axis direction. Each of the source openings 26A and each of the drain openings 26B extend in the Y-axis direction in plan view. In the present embodiment, the X-axis direction corresponds to the “first direction”, and the Y-axis direction corresponds to the “second direction”. Therefore, the second direction is orthogonal to the first direction in plan view.

A length of each source opening 26A in the Y-axis direction is equal to a length of each drain opening 26B in the Y-axis direction. In addition, each source opening 26A and each drain opening 26B are aligned with each other in the Y-axis direction. That is, as shown in FIG. 3, a first end portion CA1 of each source opening 26A and a first end portion CB1 of each drain opening 26B are aligned with each other in the Y-axis direction, and a second end portion CA2 of each source opening 26A and second end portion CB2 of each drain opening 26B are aligned with each other in the Y-axis direction. The first end portion CA1 of each source opening 26A refers to one of the two end portions of the source opening 26A located closer to the first inactive region 104 in the Y-axis direction. The second end portion CA2 of each source opening 26A refers to one of the two end portions of the source opening 26A in the Y-axis direction located closer to the second inactive region 106A (second inactive region 106B). The first end portion CB1 of each drain opening 26B refers to one of the two end portions of the drain opening 26B in the Y-axis direction located closer to the first inactive region 104. The second end portion CB2 of the drain opening 26B refers to one of the two end portions of the drain opening 26B in the Y-axis direction located closer to the second inactive region 106A (second inactive region 106B).

In the illustrated example, every two of the plurality of source openings 26A are separated from each other in the Y-axis direction and arranged in a line. In addition, every two of the plurality of drain openings 26B are separated from each other in the Y-axis direction and arranged in a line.

Each source opening 26A is filled with the source contact portion 28A, and the drain opening 26B is filled with the drain contact portion 30A. Thus, the plurality of source contact portions 28A and the plurality of drain contact portions 30A are alternately formed one by one in the X-axis direction. In addition, the source contact portion 28A and the drain contact portion 30A adjacent to each other in the X-axis direction are separated from each other in the X-axis direction. Every two of the plurality of source contact portions 28A are separated from each other in the Y-axis direction and arranged in a line. Every two of the plurality of drain contact portions 30A are separated from each other in the Y-axis direction and arranged in a line.

Each of the source contact portions 28A and each of the drain contact portions 30A extend in the Y-axis direction in plan view. The source field plate portion 28B (refer to FIG. 1) is formed over substantially the entire formation pattern 100. In the source field plate portion 28B, a plurality of drain electrode openings 28D forming the end portion 28C are formed. A drain electrode 30 is formed in each of the drain electrode openings 28D. In other words, the source field plate portion 28B is formed so as to surround the drain electrode 30 in plan view.

The drain plate portion 30B of the drain electrode 30 is formed at a distance from the end portion 28C forming each drain electrode opening 28D. In plan view, the drain plate portion 30B has the form of a strip extending in the Y-axis direction.

As shown in FIG. 3, the formation pattern 100 includes an active region 102 that contributes to transistor operation, and a first inactive region 104 and a second inactive region 106 that do not contribute to transistor operation. In the illustrated example, the active region 102, the first inactive region 104, and the second inactive region 106 are partitioned in the Y-axis direction. That is, the active region 102, the first inactive region 104, and the second inactive region 106 are formed side by side in the Y-axis direction.

The active region 102 includes the source electrode 28, the drain electrode 30, and the gate electrode 24. The active region 102 refers to a region in which a current flows between the source and the drain when a voltage is applied to the gate electrode 24. The active region 102 extends in the X-axis direction. The active region 102 includes the source opening 26A and the drain opening 26B. In the illustrated example, two source openings 26A are formed in the Y-axis direction and two drain openings 26B are formed in the Y-axis direction. Thus, two active regions 102 are formed and separated from each other in the Y-axis direction. In other words, the number of active regions 102 is set according to the number of source openings 26A (drain openings 26B) disposed in the Y-axis direction. In the following description, For the sake of convenience, the two active regions 102 are referred to as the first active region 102A and the second active region 102B. In addition, the drain opening in the first active region 102A is referred to as a “drain opening 26BA”, and the drain opening in the second active region 102B is referred to as a “drain opening 26BB”. The source opening in the first active region 102A is referred to as a “source opening 26AA”, and the source opening in the second active region 102B is referred to as a “source opening 26AB”.

In the first active region 102A, a plurality of (fourteen in the example of FIG. 2) structures of the nitride semiconductor device shown in FIG. 1 are continuously formed in the X-axis direction. Similarly, in the second active region 102B, a plurality of (fourteen in the example of FIG. 2) structures of the nitride semiconductor device shown in FIG. 1 are continuously formed in the X-axis direction. Therefore, the cross-sectional view shown in FIG. 1 corresponds to an enlarged view of a part of the cross section of the formation pattern 100 in the active region 102. Both the first active region 102A and the second active region 102B include the source opening 26A and the drain opening 26B in plan view.

Both the first inactive region 104 and the second inactive region 106 are regions where the source electrode 28 and the gate electrode 24 (not shown in FIG. 2, refer to FIG. 1) are provided, but the drain electrode 30 is not provided. The first inactive region 104 and the second inactive region 106 do not contribute to determination of the amount of current flowing between the source and the drain when a voltage is applied to the gate electrode 24.

In the illustrated example, the first inactive region 104 is formed between the first active region 102A and the second active region 102B in the Y-axis direction. That is, in plan view, the first inactive region 104 is adjacent to both the first active region 102A and the second active region 102B in the Y-axis direction. In other words, the first inactive region 104 is a region adjacent to the active region 102 in the Y-axis direction.

The second inactive region 106 is formed on a side opposite to the first inactive region 104 with respect to the active region 102 in the Y-axis direction. In other words, the second inactive region 106 is separated from the first inactive region 104 in the Y-axis direction via the source opening 26A and the drain opening 26BA. For the sake of convenience, the second inactive region formed on the side opposite to the first active region 102A in the Y-axis direction with respect to the first inactive region 104 is referred to as a “second inactive region 106A”, and the second inactive region formed on the side opposite to the first inactive region 104 in the Y-axis direction with respect to the second active region 102B is referred to as a “second inactive region 106B”. The second inactive region 106A is a region formed at a position adjacent to the first active region 102A in the Y-axis direction and separated from the second active region 102B. The second inactive region 106B is a region formed at a position adjacent to the second active region 102B in the Y-axis direction and separated from the first active region 102A.

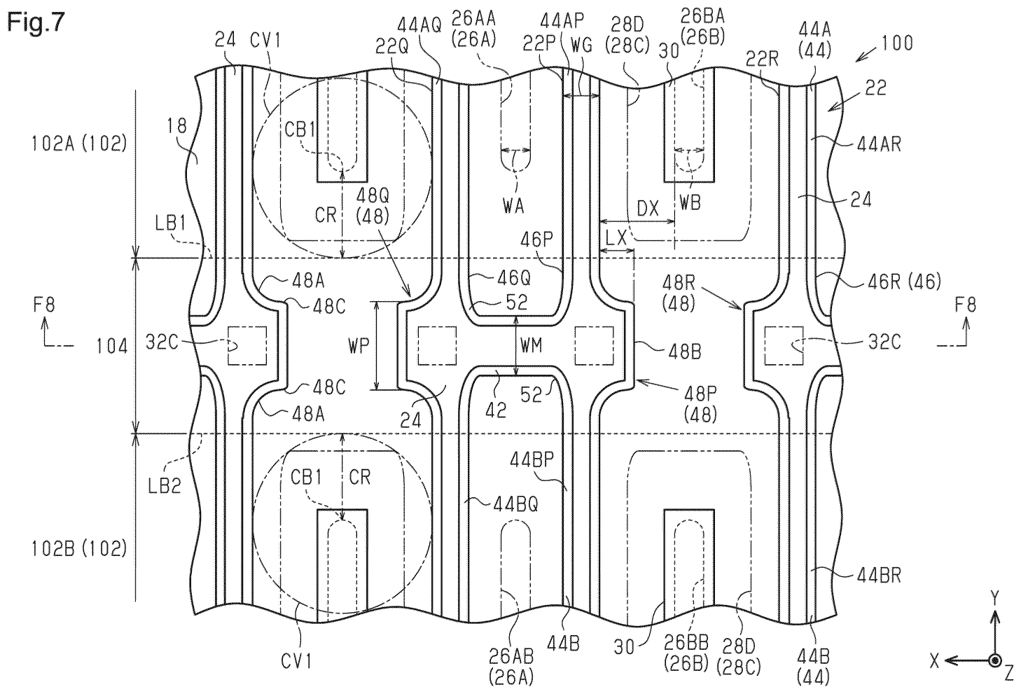

FIG. 7 is an enlarged view of the first inactive region 104 and the periphery thereof. As shown in FIG. 7, an imaginary circle CV1 having a radius CR centered on the first end portion CB1 of the drain opening 26BA is defined. The radius CR of the imaginary circle CV1 is equal to the distance between the drain contact portion 30A and the gate layer 22 in the X-axis direction in plan view.

A boundary line LB1 between the first inactive region 104 and the first active region 102A extends in the X-axis direction at a position away by a radius CR from the first end portion CB1 of the drain opening 26BA in the Y-axis direction. The boundary line LB2 between the first inactive region 104 and the second active region 102B is similar to the boundary line LB1. Therefore, the first inactive region 104 may be defined as a region between the boundary line LB1 and the boundary line LB2 in the Y-axis direction.

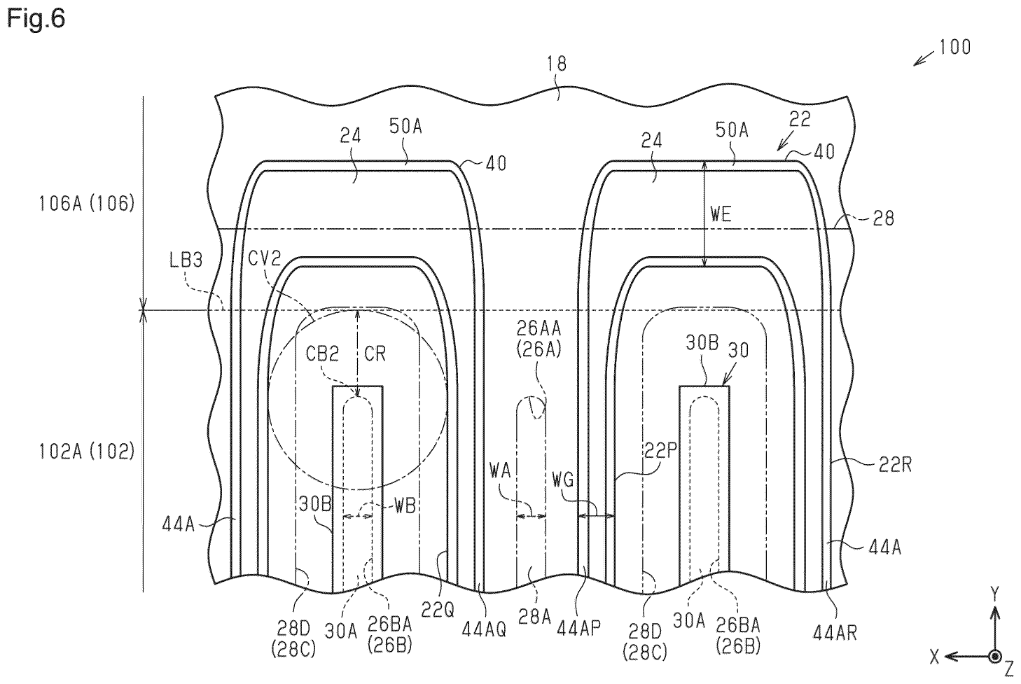

FIG. 6 is an enlarged view of the second inactive region 106A and the periphery thereof. As shown in FIG. 6, an imaginary circle CV2 having a radius CR centered on the second end portion CB2 of the drain opening 26BA is defined. The radius CR of the imaginary circle CV2 is equal to the radius CR of the imaginary circle CV1.

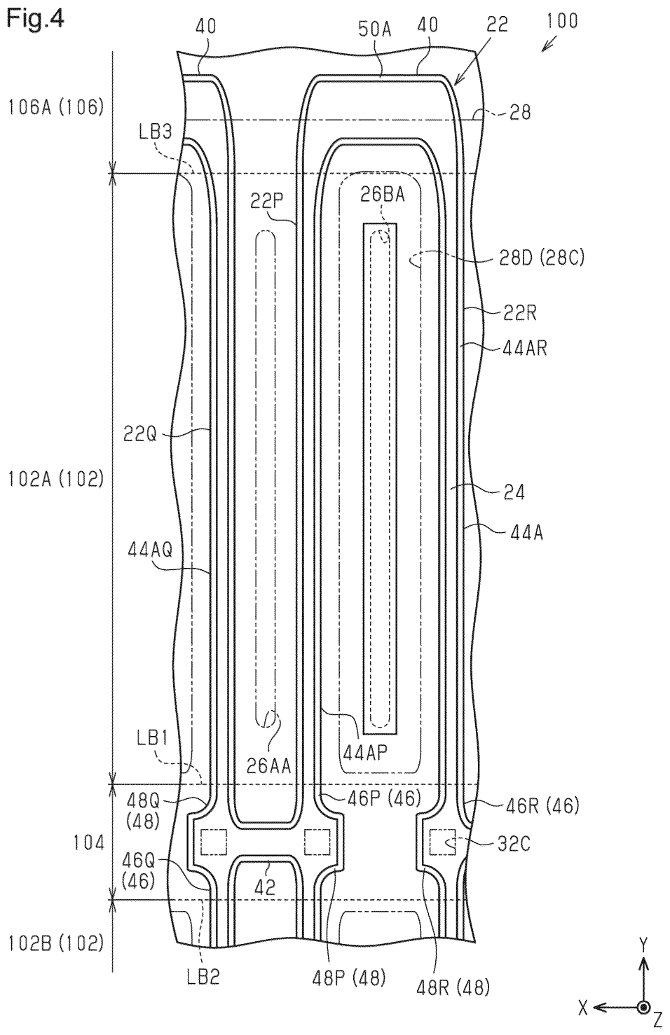

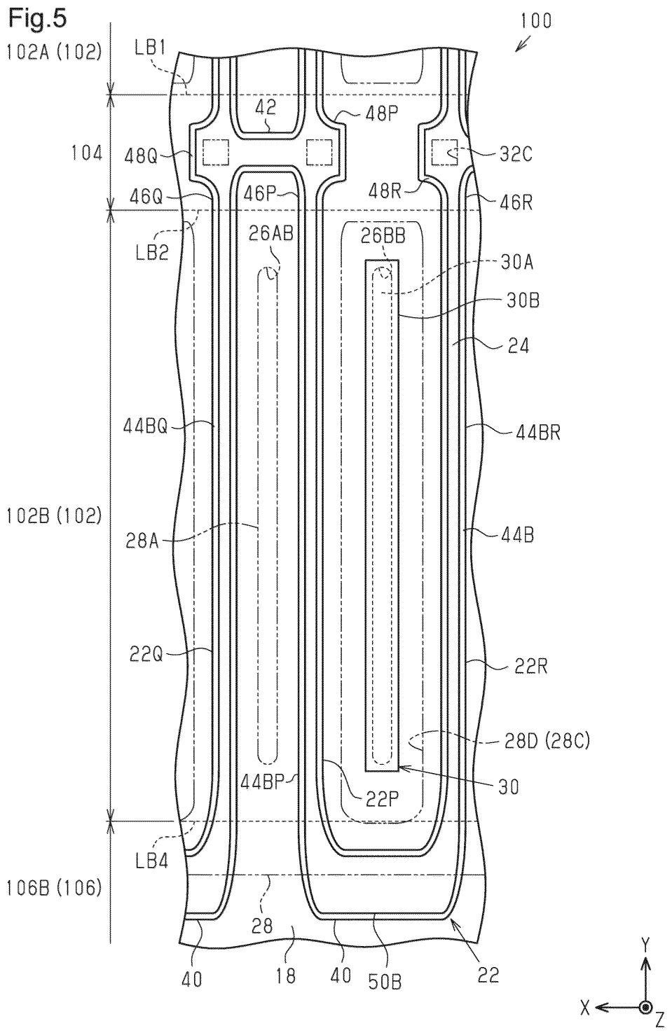

The boundary line LB3 between the second inactive region 106A and the first active region 102A extends in the X-axis direction at a position away from the first active region 102A beyond a position that is separated by the radius CR from the second end portion CB2 of the drain opening 26BA in the Y-axis direction. The boundary line LB4 between the second inactive region 106B and the second active region 102B shown in FIG. 5 is similar to the boundary line LB1. As shown in FIG. 4, the first active region 102A may be defined as the region between the boundary line LB1 and the boundary line LB3 in the Y-axis direction. As shown in FIG. 5, the second active region 102B may be defined as a region between the boundary line LB2 and the boundary line LB4 in the Y-axis direction.

As shown in FIGS. 3 to 5, the gate layer 22 is continuously formed in the Y-axis direction over the first active region 102A, the second active region 102B, the first inactive region 104, and the second inactive regions 106A and 106B. Although not illustrated, in the present embodiment, the source electrode 28 is continuously formed in the Y-axis direction over the first active region 102A, the second active region 102B, the first inactive region 104, and a part of the second inactive regions 106A and 106B.

As shown in FIG. 2, the source wiring 34 and the drain wiring 36 are disposed in the active region 102. More specifically, in the illustrated example, in the first active region 102A, two source wirings 34 and two drain wirings 36 are alternately arranged one by one in the Y-axis direction. The two source wirings 34 and the two drain wirings 36 are disposed at intervals in the Y-axis direction. Each of the source wirings 34 and each of the drain wirings 36 extend in the X-axis direction. Similarly, in the second active region 102B, two source wirings 34 and two drain wirings 36 are alternately arranged one by one in the Y-axis direction. The number of the source wirings 34 and the drain wirings 36 may be changed in any manner.

The gate wiring 38 is disposed in each of the first inactive region 104 and the second inactive regions 106A and 106B. More specifically, one gate wiring 38 is disposed in the first inactive region 104. One gate wiring 38 is disposed in each of the second inactive regions 106A and 106B. Each gate wiring 38 extends in the X-axis direction. In the first inactive region 104 and the second inactive regions 106A and 106B, the gate wiring 38 is connected to the gate electrode 24 (refer to FIG. 1) on the gate layer 22 through the gate wiring opening 32C.

### Planar Structure of Gate Layer and Gate Electrode

As shown in FIG. 3, the gate layer 22 includes a ring-shaped portion 40 formed in a ring shape so as to surround two drain openings 26BA and 26BB disposed in a row in the Y-axis direction. A plurality of ring-shaped portions 40 are separated from each other in the X-axis direction. The ring-shaped portions 40 adjacent to each other in the X-axis direction are connected by a first connection portion 42. As described above, in the present embodiment, the gate layer 22 includes the plurality of ring-shaped portions 40 and the plurality of first connection portions 42.

The gate layer 22 includes a main gate portion 44 extending in the Y-axis direction in the active region 102 and a sub gate portion 46 extending in the Y-axis direction so as to be continuous with the main gate portion 44 in the first inactive region 104. Both the main gate portion 44 and the sub gate portion 46 are parts forming the ring-shaped portion 40. The main gate portion 44 is provided in both the first active region 102A and the second active region 102B. For the sake of convenience, the main gate portion in the first active region 102A is referred to as a “main gate portion 44A”, and the main gate portion in the second active region 102B is referred to as a “main gate portion 44B”.

A plurality of main gate portions 44A are formed in the first active region 102A and separated from each other in the X-axis direction. The main gate portion 44A is disposed one by one between the source opening 26AA and the drain opening 26BA adjacent to each other in the X-axis direction. In plan view, the main gate portion 44A extends over the entire first active region 102A in the Y-axis direction.

A plurality of main gate portions 44B are formed in the second active region 102B and separated from each other in the X-axis direction. The main gate portion 44B is disposed one by one between the source opening 26AB and the drain opening 26BA adjacent to each other in the X-axis direction. In plan view, the main gate portion 44B extends over the entire second active region 102B in the Y-axis direction. As described above, the source openings 26AA and 26AB and the drain openings 26BA and 26BB are provided at opposite sides of the gate layer 22 in the X-axis direction.

The sub gate portion 46 is located between the main gate portion 44A and the main gate portion 44B in the Y-axis direction. The sub gate portion 46 connects the main gate portion 44A and the main gate portion 44B. The plurality of sub gate portions 46 are separated from each other in the X-axis direction. The plurality of sub gate portions 46 individually connect the plurality of main gate portions 44A and the plurality of main gate portions 44B.

The gate layer 22 includes a protrusion 48 protruding from the sub gate portion 46 toward the drain openings 26BA and 26BB in the X-axis direction. The gate layer 22 includes a plurality of protrusions 48. The plurality of protrusions 48 are individually formed in the plurality of sub gate portions 46. The protrusions 48 adjacent to each other in the X-axis direction are separated from each other in the X-axis direction. The two protrusions 48 formed on one ring-shaped portion 40 face each other in the X-axis direction. The passivation layer 26 and the source electrode 28 are located between the two protrusions 48 in the X-axis direction (refer to FIG. 8).

The main gate portions 44A and 44B and the sub gate portions 46 both are disposed closer to the source openings 26AA and 26AB than to the drain openings 26BA and 26BB in the X-axis direction in plan view. In other words, the distance between the main gate portion 44A and the drain opening 26BA in the X-axis direction is larger than the distance between the main gate portion 44A and the source opening 26AA in the X-axis direction. In other words, the distance between the main gate portion 44B and the drain opening 26BB in the X-axis direction is larger than the distance between the main gate portion 44B and the source opening 26AB in the X-axis direction. In other words, the distance between the sub gate portion 46 and the drain openings 26BA and 26BB in the X-axis direction is larger than the distance between the sub gate portion 46 and the source openings 26AA and 26AB in the X-axis direction.

As shown in FIG. 6, a width WG of the main gate portion 44A is greater than a width WA of source opening 26AA. The width WG of the main gate portion 44A is greater than the width WB of the drain opening 26BA. The width WG of the main gate portion 44A is defined by the size of the main gate portion 44A in the X-axis direction in the first active region 102A. The width WA of the source opening 26AA is defined by, for example, the size, in the X-axis direction, of the central portion in the Y-axis direction of the source opening 26AA. The width WB of the drain opening 26BA is defined by, for example, the size, in the X-axis direction, of the central portion in the Y-axis direction of the drain opening 26BA. The width of the main gate portion 44B (refer to FIG. 5) is equal to the width WG of the main gate portion 44A.

The width WG of the main gate portion 44A may be changed in any manner. In one example, the width WG of the main gate portion 44A may be equal to or less than the width WA of the source opening 26AA. The width WG of the main gate portion 44A may be equal to or less than the width WB of the drain opening 26BA.

In FIGS. 4 and 5, the gate layer 22 may be partitioned into a first gate layer 22P, a second gate layer 22Q, and a third gate layer 22R. Thus, in other words, that the gate layer 22 includes the first gate layer 22P, the second gate layer 22Q, and the third gate layer 22R. The first gate layer 22P is a portion of the gate layer 22 disposed between a predetermined source opening 26AA (26AB) and a drain opening 26BA (26BB) adjacent to the predetermined source opening 26AA in the X-axis direction. The second gate layer 22Q is a portion of the gate layer 22 separated from the first gate layer 22P in the X-axis direction via the predetermined source opening 26AA (26AB) in plan view. The third gate layer 22R is a portion of the gate layer 22 separated from the first gate layer 22P in the X-axis direction via the drain opening 26BA (26BB) in plan view. That is, the first gate layer 22P is disposed between the second gate layer 22Q and the third gate layer 22R in the X-axis direction. In FIGS. 4 and 5, the first gate layer 22P and second gate layer 22Q form one ring-shaped portion 40, and the third gate layer 22R forms another ring-shaped portion 40.

As shown in FIGS. 4 and 5, each of the first to third gate layers 22P to 22R extends over the first active region 102A, the first inactive region 104, and the second active region 102B in the Y-axis direction. Therefore, the first gate layer 22P includes first main gate portions 44AP and 44BP as the main gate portions 44 A and 44B, a first sub gate portion 46P as the sub gate portion 46, and a first protrusion 48P as the protrusion 48. The second gate layer 22Q includes second main gate portions 44AQ and 44BQ as main gate portions 44 A and 44B, a second sub gate portion 46Q as the sub gate portion 46, and a second protrusion 48Q as the protrusion 48. The third gate layer 22R includes third main gate portions 44AR and 44BR as the main gate portions 44A and 44B, a third sub gate portion 46R as the sub gate portion 46, and a third protrusion 48R as the protrusion 48.

As shown in FIG. 4, the gate layer 22 includes a second connection portion 50A that connects the first main gate portion 44AP and the third main gate portion 44AR in the second inactive region 106A. Therefore, the drain opening 26BA is surrounded by the first main gate portion 44AP, the third main gate portion 44AR, and the second connection portion 50A. As described above, the second connection portion 50A connects the main gate portions 44A (44AP, 44AR) disposed at opposite sides of the drain opening 26BA in the X-axis direction in the second inactive region 106A.

As shown in FIG. 5, the gate layer 22 includes a second connection portion 50B that connects the first main gate portion 44BP and the third main gate portion 44BR in the second inactive region 106B. Therefore, the drain opening 26BB is surrounded by the first main gate portion 44BP, the third main gate portion 44BR, and the second connection portion 50B. As described above, the second connection portion 50B connects the main gate portions 44B (44BP, 44BR) disposed at opposite sides of the drain opening 26BB in the X-axis direction in the second inactive region 106B.

As shown in FIG. 3, the second connection portions 50A and 50B are portions forming the ring-shaped portion 40. The ring-shaped portion 40 is formed by two main gate portions 44A disposed at opposite sides in the X-axis direction of the drain opening 26BA, two main gate portions 44B disposed at opposite sides in the X-axis direction of the drain opening 26BB, a sub gate portion 46 connecting the main gate portions 44A and 44B, a second connection portion 50A connecting the two main gate portions 44A, and a second connection portion 50B connecting the two main gate portions 44B.

As shown in FIG. 6, the width WE of the second connection portion 50A is greater than the width WG of the main gate portion 44A. In one example, the width WE of the second connection portion 50A is twice or more the width WG of the main gate portion 44A. The width WE of the second connection portion 50A is equal to or less than three times the width WG of the main gate portion 44A. The width WE of the second connection portion 50A is defined by the size in the Y-axis direction of a portion of the second connection portion 50A extending in the X-axis direction. The width of the second connection portion 50B is equal to the width WE of the second connection portion 50A.

As shown in FIG. 4, the distance between the drain opening 26BA and the main gate portion 44A in the X-axis direction is larger than the distance between the source opening 26AA and the main gate portion 44A in the X-axis direction, and thus the length of the second connection portion 50A in the X-axis direction is greater than the length of the first connection portion 42 in the X-axis direction. In other words, the length of the first connection portion 42 in the X-axis direction is shorter than the length of the second connection portion 50A in the X-axis direction. As shown in FIG. 5, the length of the second connection portion 50B in the X-axis direction is equal to the length of the second connection portion 50A in the X-axis direction.

As shown in FIGS. 4 and 5, the first connection portion 42 connects the first sub gate portion 46P and the second sub gate portion 46Q in the first inactive region 104. Therefore, the ring-shaped portion 40 including the first sub gate portion 46P and the ring-shaped portion 40 including the second sub gate portion 46Q are formed at positions different from each other and adjacent to each other in the X-axis direction. The ring-shaped portion 40 including the first sub gate portion 46P includes the third sub gate portion 46R. Each of the first connection portions 42 is separated from each other in the X-axis direction. Each of the first connection portions 42 is formed in the first inactive region 104. Each of the first connection portions 42 extends in the X-axis direction. The first connection portion 42 is disposed on the side opposite to the protrusions 48P and 48Q with respect to both the sub gate portions 46P and 46Q in the X-axis direction. Both the protrusions 48P and 48Q are formed at positions aligned with the first connection portion 42 in the Y-axis direction among the sub gate portions 46P and 46Q.

As shown in FIG. 4, a source opening 26AA is surrounded by a first main gate portion 44AP, a second main gate portion 44AQ, the first sub gate portion 46P, the second sub gate portion 46Q, and the first connection portion 42. As shown in FIG. 5, a source opening 26AB is surrounded by a first main gate portion 44BP, a second main gate portion 44BQ, the first sub gate portion 46P, the second sub gate portion 46Q, and the first connection portion 42.

As shown in FIG. 7, the width WM of the first connection portion 42 is greater than the width WG of the main gate portion 44A. The width WM of the first connection portion 42 is smaller than the width WE of the second connection portion 50A (refer to FIG. 6). In one example, the width WM of the first connection portion 42 is less than twice the width WG of the main gate portion 44A. The width WM of the first connection portion 42 is defined by the size in the Y-axis direction of the first connection portion 42.

As shown in FIGS. 3 to 5, the gate electrode 24 is formed so as to have a shape slightly smaller than the gate layer 22 in plan view. That is, in plan view, the gate electrode 24 has a shape similar to that of the gate layer 22.

### Configuration of Protrusion 48 and Periphery Thereof

Then, detailed configuration of the protrusion 48 and the periphery thereof will be described. In the following description, the description common to the first protrusion 48P, the second protrusion 48Q, and the third protrusion 48R will be described as the protrusion 48.

As shown in FIG. 7, the first protrusion 48P protrudes from the first sub gate portion 46P toward the third protrusion 48R in the X-axis direction. The third protrusion 48R protrudes from the third sub gate portion 46R toward the first protrusion 48P in the X-axis direction. That is, the first protrusion 48P and the third protrusion 48R protrude so as to approach each other in the ring-shaped portion 40 including the first gate layer 22P and the third gate layer 22R. On the other hand, the first protrusion 48P and the third protrusion 48R are separated from each other in the X-axis direction.

The second protrusion 48Q protrudes from the second sub gate portion 46Q toward the side opposite to the first protrusion 48P in the X-axis direction. Therefore, the protruding direction of the second protrusion 48Q from the second sub gate portion 46Q is the same as the protruding direction of the third protrusion 48R from the third sub gate portion 46R.

In plan view, the plurality of protrusions 48 have the same shape. Each protrusion 48 has a substantially trapezoidal shape in plan view. More specifically, each protrusion 48 includes two side surfaces 48A, a distal end surface 48B, and two connection portions 48C that connects the two side surfaces 48A and the distal end surface 48B.

The two side surfaces 48A include a portion formed in a curved shape. More specifically, the side surface 48A closer to the drain opening 26BA includes a portion formed so as to have a curved convex shape away from the drain opening 26BA toward the distal end surface 48B. The side surface 48A closer to the drain opening 26BB includes a portion formed so as to have a curved convex shape away from the drain opening 26BB toward the distal end surface 48B. In one example, the radius of curvature of each side surface 48A is smaller than the radius of curvature of the second connection portion 50A (refer to FIG. 6).

The distal end surface 48B extends in the Y-axis direction in plan view. That is, the distal end surface 48B is a flat surface along the YZ plane. The distal end surface 48B may be an inclined surface that is inclined such that the protrusion length LX increases toward the electron supply layer 18. Herein, the protrusion length LX is defined by a distance between the sub gate portion 46 and the distal end surface 48B of the protrusion 48 in the X-axis direction.

The connection portion 48C is formed in a curved shape in plan view. The radius of curvature of the connection portion 48C is smaller than the radius of curvature of each side surface 48A.

The distal end surface 48B of the protrusion 48 is located closer to the sub gate portion 46 than a central position in the X-axis direction between the sub gate portion 46 and the drain opening 26BA in the X-axis direction. That is, the protrusion length LX of the protrusion 48 from the sub gate portion 46 is less than ½ of the distance DX between the sub gate portion 46 and the drain opening 26BA in the X-axis direction. In one example, the protrusion length LX is equal to or less than the width WG of the main gate portion 44A. In the illustrated example, the protrusion length LX is equal to the width WG of the main gate portion 44A.

The width WP of the protrusion 48 is greater than the width WG of the main gate portion 44A. The width WP of the protrusion 48 is greater than the width WM of the first connection portion 42. In other words, the width WM of the first connection portion 42 is smaller than the width WP of the protrusion 48. The width WP of the protrusion 48 is smaller than the width WE of the second connection portion 50A. Herein, the width WP of the protrusion 48 is defined by the size in the Y-axis direction at the distal end portion of the protrusion 48.

The connecting portion 52 of the sub gate portion 46 connected to the first connection portion 42 is formed in a curved shape. The connecting portion 52 is formed so as to have a curved convex shape in a direction away from the source openings 26AA and 26AB toward the first connection portion 42. In one example, the radius of curvature of the connecting portion 52 is greater than the radius of curvature of each side surface 48A of the protrusion 48. In other words, the curvature radius of each side surface 48A is smaller than the curvature radius of the connecting portion 52.

As shown in FIG. 7, the gate wiring opening 32C is formed over both protrusion 48 and sub gate portion 46 in the X-axis direction in plan view. In other words, the gate wiring opening 32C is formed so as to straddle the boundary between the protrusion 48 and the sub gate portion 46 in plan view.

The gate wiring opening 32C has a rectangular shape in plan view. In one example, the length of the gate wiring opening 32C in the X-axis direction is greater than the width WA of the source opening 26AA. In one example, the length of the gate wiring opening 32C in the X-axis direction is greater than the width WB of the drain opening 26BA. In one example, the length of the gate wiring opening 32C in the X-axis direction is equal to or greater than the width WG of the main gate portion 44A. The length of the gate wiring opening 32C in the Y-axis direction is less than the width WP of the protrusion 48.

As shown in FIG. 8, the source electrode 28 includes a gate electrode opening 28E formed at a position corresponding to each gate wiring opening 32C. An interlayer insulating layer 32 is interposed between the gate electrode opening 28E and the gate wiring opening 32C. Thus, the gate wiring 38 (also referred to as a contact of gate wiring 38) filling the gate wiring opening 32C and the source electrode 28 are electrically insulated.

### Operation

The action of the nitride semiconductor device 10 of the present embodiment will be described.

The gate current flows from, for example, an external control device to the gate electrode 24 via the gate wiring 38. Therefore, at the connecting portion between the gate wiring 38 and the gate electrode 24, that is, the portion of the gate electrode 24 overlapping with the gate wiring opening 32C in a plan view, the gate current tends to concentrate as compared with the other portion of the gate electrode 24. As described above, the local concentration of the gate current in the gate electrode 24 may cause a decrease in reliability of the gate electrode 24.

In the first inactive region 104, the protrusion 48 is provided in the sub gate portion 46, and thus the area of a portion of the gate layer 22 overlapping the gate wiring opening 32C in plan view increases. As a result, the area of the portion of the gate electrode 24 on the gate layer 22 formed over the sub gate portion 46 and the protrusion 48 also increases. Therefore, when the gate current is supplied to the gate electrode 24 through the gate wiring 38, the gate current easily flows and is dispersed in the gate electrode 24 on the main gate portion 44A and the gate electrode 24 on the main gate portion 44B. As a result, local concentration of the gate current in the gate electrode 24 is limited.

In addition, for example, in a configuration in which one gate wiring opening 32C is formed at a position overlapping the first connection portion 42 in plan view (hereinafter, “comparative configuration”), the gate current flows to the two main gate portions 44A and the two main gate portions 44B via the contact of the gate wiring 38 provided in the gate wiring opening 32C. In this case, the gate current flows with one contact to the four main gate portions 44A and 44B, and thus local concentration of the gate current in the gate electrode 24 is likely to occur. In addition, the electric resistance of the corresponding gate electrode 24 is applied between the first connection portion 42 and the main gate portions 44A and 44B, and thus the electric resistance between the gate wiring 38 and the gate electrode 24 increases.

Further, in the comparative configuration, the length of the gate electrode 24 through which the gate current flows to one contact of the gate wiring 38 becomes long, and thus the time for supplying the gate current to the four main gate portions 44A and 44B of the gate electrode 24 becomes long.

In this regard, in the present embodiment, the gate wiring opening 32C extends over both of each sub gate portion 46 and each protrusion 48 in plan view, and thus a gate current flows from one contact of the gate wiring 38 to two main gate portions 44A and 44B. This reduces local concentration of the gate current in the gate electrode 24. In addition, it is not necessary to consider the electric resistance of the gate electrode 24 corresponding between the first connection portion 42 and the main gate portions 44A and 44B, and thus an increase in the electric resistance between the gate wiring 38 and the gate electrode 24 is likely to be reduced. Further, in the present embodiment, the length of the gate electrode 24 through which the gate current flows to one contact of the gate wiring 38 is shorter than that in the comparative configuration, and thus the time for supplying the gate current to the main gate portions 44A and 44B is shortened.

In the second inactive region 106A, the width WE of the second connection portion 50A of the gate layer 22 is large, and thus the width of the gate electrode 24 on the second connection portion 50A is also large. Therefore, in the gate electrode 24 on the second connection portion 50A, the gate wiring 38 is connected via the gate wiring opening 32C, but the concentration of the gate current is reduced. Similarly, the concentration of the gate current is reduced for the gate electrode 24 on the second connection portion 50B in the second inactive region 106B.

### Effects

According to the nitride semiconductor device 10 of the present embodiment, the following effects may be obtained.

(1-1) A nitride semiconductor device 10 includes: an electron supply layer 18 including a nitride semiconductor; a gate layer 22 formed on a part of the electron supply layer 18 by a nitride semiconductor containing an acceptor impurity; a gate electrode 24 formed on the gate layer 22; a passivation layer 26 that covers the electron supply layer 18, the gate layer 22, and the gate electrode 24 and has a source opening 26A and a drain opening 26B provided at opposite sides of the gate layer 22 in the X-axis direction in plan view; a source electrode 28 in contact with the electron supply layer 18 exposed by the source opening 26A; a drain electrode 30 in contact with the electron supply layer 18 exposed by the drain opening 26B; an active region 102 extending in the X-axis direction and including the source opening 26A and the drain opening 26B; and a first in active region 104 adjacent to the active region 102 in the Y-axis direction orthogonal to the X-axis direction in plan view. The gate layer 22 includes a main gate portion 44 extending in the Y-axis direction in the active region 102, a sub gate portion 46 extending in the Y-axis direction so as to be continuous with the main gate portion 44 in the first inactive region 104, and a protrusion 48 protruding from the sub gate portion 46 toward the drain opening 26B in the X-axis direction.

According to this configuration, the gate electrode 24 is formed over both the sub gate portion 46 and the protrusion 48 in the first inactive region 104. Therefore, when the gate current is supplied to the gate electrode 24 via the gate wiring 38, concentration of the gate current in the gate electrode 24 is reduced. Therefore, current concentration in the gate electrode 24 is less likely to occur. This limits a decrease in gate reliability such as a local excessive increase in the temperature of the gate electrode 24.

(1-2) A distal end of the protrusion 48 is located closer to the sub gate portion 46 than the central position in the X-axis direction between the sub gate portion 46 and the drain opening 26B in the X-axis direction. In other words, the protrusion length LX of the protrusion 48 is less than ½ of the distance DX between the main gate portion 44 and the drain opening 26B in the X-axis direction.

This configuration allows for an increase in the distance between the protrusion 48 and the drain opening 26B in plan view. Accordingly, the distance between the protrusion 48 and the drain electrode 30 is increased, and thus a parasitic capacitance between the protrusion 48 and the drain electrode 30 is reduced. This achieves both reduction of concentration of the gate current by the protrusion 48 and reduction of the parasitic capacitance between the protrusion 48 and the drain electrode 30.

(1-3) The nitride semiconductor device 10 further includes an interlayer insulating layer 32 covering the source electrode 28 and the passivation layer 26. A gate wiring opening 32C is formed in both the interlayer insulating layer 32 and the passivation layer 26 as a gate opening for exposing the gate electrode 24. The gate wiring opening 32C is formed over both the protrusion 48 and the sub gate portion 46 in the X-axis direction in plan view.

This configuration allows for an increase in the area of the gate wiring opening 32C in plan view, thereby increasing the connection area between the gate wiring 38 and the gate electrode 24. This reduces the electrical resistance between the gate wiring 38 and the gate electrode 24.

In addition, a part of the gate wiring opening 32C is formed at a position overlapping the sub gate portion 46 in plan view, and thus the gate current from the gate wiring 38 flows to the main gate portion 44 via the sub gate portion 46. Therefore, for example, as compared with the configuration in which the gate wiring opening 32C is formed in the first connection portion 42, the current path of the gate current flowing from the gate wiring 38 toward the main gate portion 44 is shortened. This reduces the electrical resistance in the gate electrode 24.

(1-4) A width WP of the protrusion 48 is greater than a width WG of the main gate portion 44.

According to this configuration, the total area of the protrusion 48 and the sub gate portion 46 where the protrusion 48 is continuous in plan view is increased, and thus the area of the protrusion 48 and the gate electrode 24 on the sub gate portion 46 in plan view is increased. With this configuration, when the gate current is supplied to the gate electrode 24 via the gate wiring 38, concentration of the gate current in the gate electrode 24 is easily reduced.

(1-5) Both the main gate portion 44 and the sub gate portion 46 are disposed closer to the source opening 26A than to the drain opening 26B in the X-axis direction.

This configuration allows for an increase in the distance between the sub gate portion 46 and the drain opening 26B in the X-axis direction. With this configuration, even if the protrusion length LX of the protrusion 48 from the sub gate portion 46 is increased, that is, the area of the protrusion 48 and the gate electrode 24 on the sub gate portion 46 in plan view is increased, the distance between the protrusion 48 and the drain opening 26B is increased. This achieves both reduction of concentration of the gate current by the protrusion 48 and reduction of the parasitic capacitance between the protrusion 48 and the drain electrode 30.

(1-6) The distance between the protrusion 48 and the first end portion CB1 of the drain opening 26B in the Y-axis direction is greater than or equal to the distance DX between the drain opening 26B and the main gate portion 44 in the X-axis direction. This configuration allows for an increase in the distance between the protrusion 48 and the drain opening 26B. This reduces the parasitic capacitance between the protrusion 48 and the drain electrode 30.

(1-7) The width WM of the first connection portion 42 is smaller than the width WP of the protrusion 48.

This configuration allows for an increase in the distance between the source opening 26A and the first connection portion 42 in the Y-axis direction. This reduces a gate leakage current flowing along the surface of the electron supply layer 18 between the gate electrode 24 and the source electrode 28.

(1-8) The width WE of the second connection portion 50A is greater than the width WG of the main gate portion 44.

This configuration allows for an increase in the width of the gate electrode 24 on the second connection portion 50A. Thus, concentration of the gate current is reduced.

### Second Embodiment

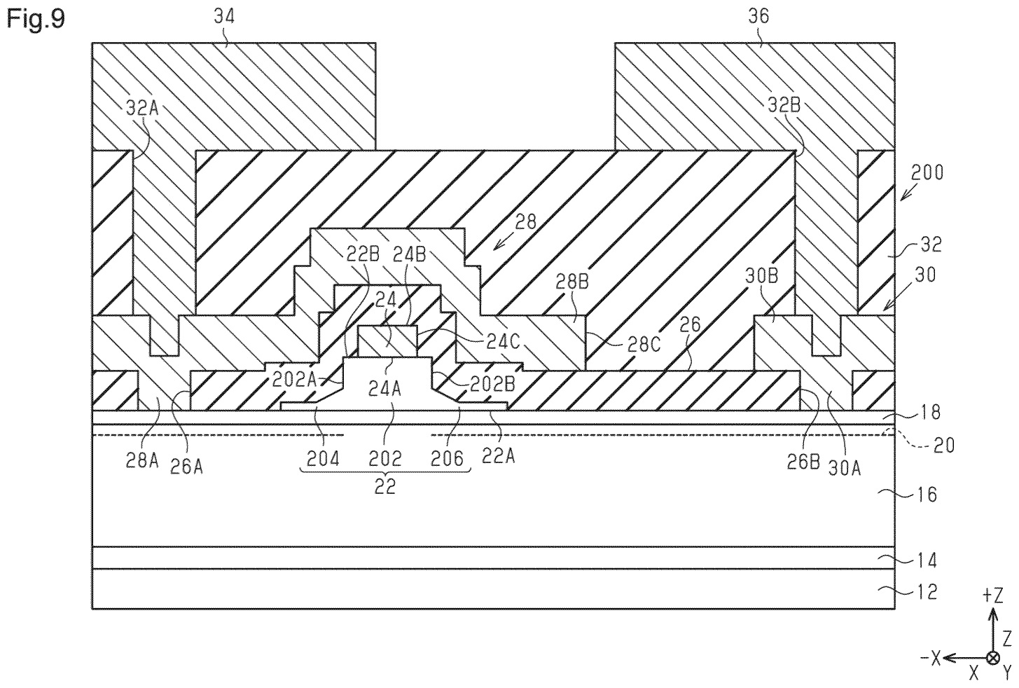

A nitride semiconductor device 200 according to a second embodiment will be described with reference to FIGS. 9 to 11. In the following description, the same components as those of the nitride semiconductor device 10 according to the first embodiment are denoted by the same reference numerals. Detailed description of components similar to those of the first embodiment will be omitted.

FIG. 9 is a schematic cross-sectional view of an exemplary nitride semiconductor device 200 according to a second embodiment.

In the exemplary nitride semiconductor device 200 according to the second exemplary embodiment, a configuration of the gate layer 22 is different from that of the first exemplary embodiment. More specifically, as shown in FIG. 9, the main gate portion 44 of the gate layer 22 includes a main ridge portion 202, a first extension portion 204, and a second extension portion 206. The main ridge portion 202 includes a portion of the main gate portion 44 where the gate electrode 24 is located. The main ridge portion 202 corresponds to the main gate portion 44 of the first embodiment. The first extension portion 204 extends from the main ridge portion 202 toward the source opening 26A. The second extension portion 206 extends from the main ridge portion 202 toward the drain opening 26B.

The main ridge portion 202 is a portion of the gate layer 22 including the upper surface 22B in contact with the gate electrode 24. The main ridge portion 202 includes a first ridge end portion 202A and a second ridge end portion 202B. The first ridge end portion 202A is an end portion of the main ridge portion 202 located close to the source opening 26A, and the second ridge end portion 202B is an end portion of the main ridge portion 202 located close to the drain opening 26B.

The first extension portion 204 extends from the main ridge portion 202 toward the source opening 26A in plan view. The first extension portion 204 is adjacent to the first ridge end portion 202A. That is, the first extension portion 204 extends from the first ridge end portion 202A toward the source opening 26A in plan view. The first extension portion 204 is separated from the source opening 26A.

The second extension portion 206 extends from the main ridge portion 202 toward the drain opening 26B in plan view. The second extension portion 206 is adjacent to the second ridge end portion 202B. That is, the second extension portion 206 extends from the second ridge end portion 202B toward the drain opening 26B in plan view. The second extension portion 206 is separated from the drain opening 26B.

The main ridge portion 202 is located between the first extension portion 204 and the second extension portion 206. The main ridge portion 202 is formed integrally with the first extension portion 204 and the second extension portion 206. The first extension portion 204 and the second extension portion 206 allow the bottom surface 22A of the gate layer 22 to have a larger area than the upper surface 22B.

The main ridge portion 202 corresponds to a relatively thick portion of the gate layer 22. The main ridge portion 202 may have a thickness of 80 nm or more and 150 nm or less. The thickness of the gate layer 22 may be determined in consideration of parameters including a gate threshold voltage. In one example, the thickness of the gate layer 22 is greater than 100 nm.

Each of the first extension portion 204 and the second extension portion 206 has a smaller thickness than the main ridge portion 202. Each of the first extension portion 204 and the second extension portion 206 may have different thicknesses at different positions. In the example shown in FIG. 9, each of the first extension portion 204 and the second extension portion 206 includes a tapered portion having a thickness that gradually decreases as the distance from the main ridge portion 202 increases in a region adjacent to the main ridge portion 202, and a flat portion having a substantially constant thickness in a region located away from the main ridge portion 202 by a predetermined distance or more. Alternatively, each of the first extension portion 204 and the second extension portion 206 may include only a flat portion or only a tapered portion. In the present description, the “substantially constant thickness” means that the thickness is within a range of production variation (for example, 20%). Each of the first extension portion 204 and the second extension portion 206 can have a thickness of 5 nm or more and 100 nm or less. The flat portions of the first extension portion 204 and the second extension portion 206 excluding the tapered portion may have a thickness of 10 nm or more and 30 nm or less. In one example, the flat portions of the first extension portion 204 and the second extension portion 206 are about 15 nm.

The length of the second extension portion 206 is greater than or equal to the length of the first extension portion 204 in plan view. The length of the first extension portion 204 may be defined by the length from the first ridge end portion 202A of the main ridge portion 202 to the distal end surface of the first extension portion 204 in plan view. The length of the second extension portion 206 may be defined by the length from the second ridge end portion 202B of the main ridge portion 202 to the distal end surface of the second extension portion 206 in plan view. The length of the first extension portion 204 may be set to 0.2 μm or more and 0.3 μm or less. In one example, the length of the first extension portion 204 is about 0.25 μm. The length of the second extension portion 206 is 0.2 μm or more and 0.6 μm or less. In one example, the length of the second extension portion 206 is about 0.4 μm.

In the example shown in FIG. 9, the second extension portion 206 extends longer than the first extension portion 204 toward the outside of the main ridge portion 202 in plan view. In this case, the flat portion of the second extension portion 206 is formed in a range wider than the flat portion of the first extension portion 204.

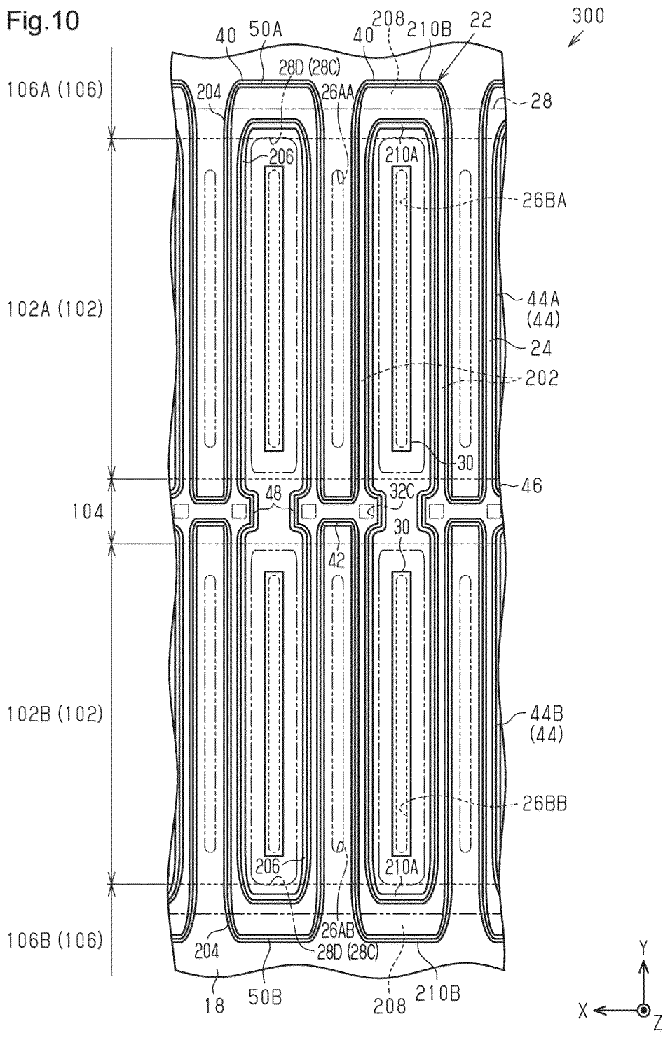

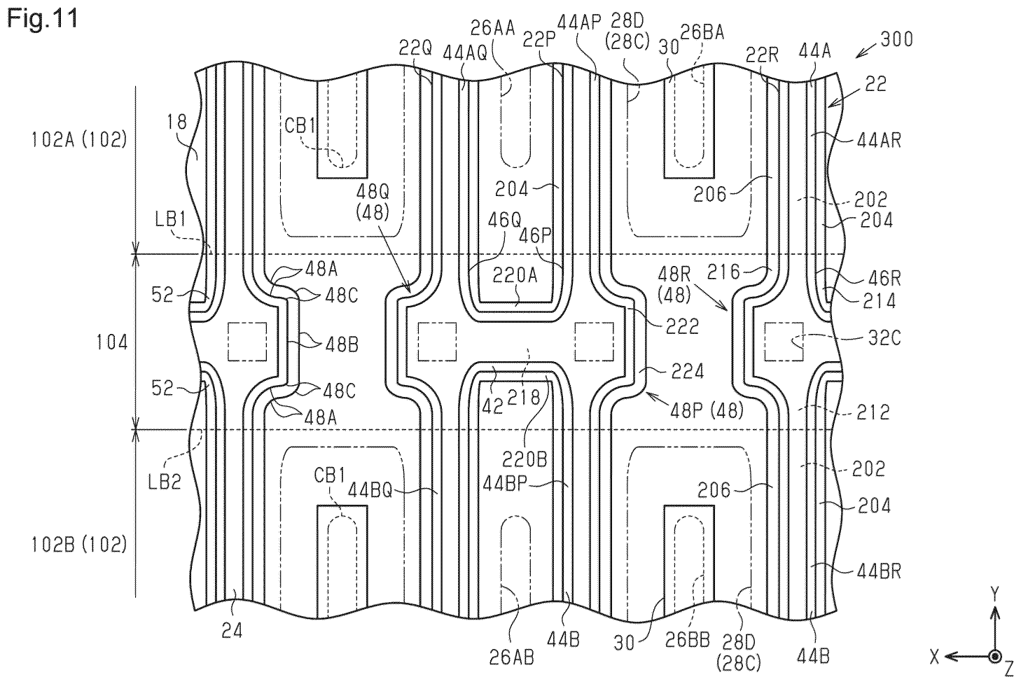

FIG. 10 is a schematic plan view showing a part of an exemplary formation pattern 300 of the nitride semiconductor device 200 shown in FIG. 9. FIG. 11 is an enlarged view of the first inactive region 104 and the periphery thereof in the formation pattern 300 shown in FIG. 10.

As shown in FIG. 10, the gate layer 22 in the second inactive region 106A may have a configuration different from that of the gate layer 22 in the active region 102. An extension portion extending from the main ridge portion 202 (refer to FIG. 9) in plan view is formed over the entire circumference of the gate layer 22. The configuration of the extension portion will be described in detail below.

In one example, the gate layer 22 in the second inactive region 106A, that is, the second connection portion 50A includes an end ridge portion 208 and two end extension portions 210A and 210B. In one example, the end ridge portion 208 and the two end extension portions 210A and 210B are integrally formed.

The end ridge portion 208 is located between the two end extension portions 210A and 210B. The end ridge portion 208 corresponds to the second connection portion 50A of the first embodiment. The end ridge portion 208 is formed continuously with the main ridge portion 202 in the second inactive region 106A. That is, the end ridge portion 208 connects the main ridge portions 202 of the main gate portions 44A disposed at opposite sides of the drain opening 26BA in the X-axis direction.

The end extension portion 210A extends from the end ridge portion 208 toward the drain opening 26BA. The end extension portion 210A is formed continuously with the second extension portion 206 in the second inactive region 106A. The end extension portion 210A is formed integrally with the second extension portion 206. In one example, the shape of the end extension portion 210A in the YZ plane is the same as the shape of the second extension portion 206 in the XZ plane.

The end extension portion 210B extends from the end ridge portion 208 toward the side opposite to the drain opening 26BA. The end extension portion 210B is formed continuously with the first extension portion 204 in the second inactive region 106A. The end extension portion 210B is formed integrally with the first extension portion 204. In one example, the shape of the end extension portion 210B in the YZ plane is the same as the shape of the first extension portion 204 in the XZ plane. Therefore, the end extension portion 210B extends longer than the end extension portion 210A toward the outside of the end ridge portion 208 in plan view.

The width of the end ridge portion 208 is greater than the width of the main ridge portion 202. The width of the end ridge portion 208 is defined by the dimension, in the Y-axis direction, of the portion of the end ridge portion 208 extending in the X-axis direction. The width of the main ridge portion 202 is defined by the dimension of the main ridge portion 202 in the X-axis direction. The second connection portion 50B, which is the gate layer 22 located in the second inactive region 106B, has the same configuration as that of the second connection portion 50A, and thus will not be described in detail.

As shown in FIG. 11, the sub gate portion 46 of the gate layer 22 in the first inactive region 104 includes a sub ridge portion 212 where the gate electrode 24 is located, a third extension portion 214 extending from the sub ridge portion 212 toward the source opening 26AA, and a fourth extension portion 216 extending from the sub ridge portion 212 toward the drain opening 26BA. In one example, the sub ridge portion 212, the third extension portion 214, and the fourth extension portion 216 are integrally formed.

The sub ridge portion 212 is located between the third extension portion 214 and the fourth extension portion 216 in the X-axis direction. The sub ridge portion 212 corresponds to the sub gate portion 46 of the first embodiment. The sub ridge portion 212 is formed continuously with the main ridge portion 202 in the first inactive region 104.

The third extension portion 214 is formed in a portion closer to the main gate portion 44A than the first connection portion 42 in the Y-axis direction and a portion closer to the main gate portion 44B than the first connection portion 42 in the Y-axis direction. The third extension portion 214 closer to the main gate portion 44A is formed continuously with the first extension portion 204 of the main gate portion 44A in the first inactive region 104. The third extension portion 214 closer to the main gate portion 44B is formed continuously with the first extension portion 204 of the main gate portion 44B in the first inactive region 104. The third extension portion 214 is formed integrally with the first extension portion 204. In one example, the shape of the third extension portion 214 in the XZ plane is the same as the shape of the first extension portion 204 in the XZ plane.

The fourth extension portion 216 is formed in a portion closer to the main gate portion 44A than the protrusion 48 in the Y-axis direction and a portion closer to the main gate portion 44B than the protrusion 48 in the Y-axis direction. The fourth extension portion 216 closer to the main gate portion 44A is formed continuously with the second extension portion 206 of the main gate portion 44A in the first inactive region 104. The fourth extension portion 216 closer to the main gate portion 44B is formed continuously with the second extension portion 206 of the main gate portion 44B in the first inactive region 104. The fourth extension portion 216 is formed integrally with the second extension portion 206. In one example, the shape of the fourth extension portion 216 in the XZ plane is the same as the shape of the second extension portion 206 in the XZ plane. Therefore, the fourth extension portion 216 extends longer than the third extension portion 214 toward the outside of the sub ridge portion 212 in plan view.

The first connection portion 42 of the gate layer 22 in the first inactive region 104 includes an intermediate ridge portion 218 extending in the X-axis direction and two intermediate extension portions 220A and 220B. In one example, the intermediate ridge portion 218 and the two intermediate extension portions 220A and 220B are integrally formed.

The intermediate ridge portion 218 is located between the two intermediate extension portions 220A and 220B in the Y-axis direction. The intermediate ridge portion 218 is formed continuously with the sub ridge portion 212 in the first inactive region 104. The intermediate ridge portion 218 corresponds to the first connection portion 42 of the first embodiment.

The intermediate extension portion 220A extends from the intermediate ridge portion 218 toward the source opening 26AA in the first inactive region 104. The intermediate extension portion 220A is formed continuously with the first extension portion 204 of the main gate portion 44A. The intermediate extension portion 220A is formed integrally with the first extension portion 204 of the main gate portion 44A. In one example, the shape of the intermediate extension portion 220A in the YZ plane is the same as the shape of the first extension portion 204 in the XZ plane.

An intermediate extension portion 220B extends from an intermediate ridge portion 218 toward the source opening 26AB in the first inactive region 104. The intermediate extension portion 220B is formed continuously with the first extension portion 204 of the main gate portion 44B. The intermediate extension portion 220B is formed integrally with the first extension portion 204 of the main gate portion 44B. In one example, the shape of the intermediate extension portion 220B in the YZ plane is the same as the shape of the first extension portion 204 in the XZ plane.

The protrusion 48 of the gate layer 22 in the first inactive region 104 includes a protruding ridge portion 222 protruding from the sub ridge portion 212 toward the drain opening 26BA in the X-axis direction, and a fifth extension portion 224 extending from the protruding ridge portion 222 in conformance with the shape of the protruding ridge portion 222 in plan view. In one example, the protruding ridge portion 222 and the fifth extension portion 224 are integrally formed.

The protruding ridge portion 222 is formed continuously with the sub ridge portion 212 in the first inactive region 104. The protruding ridge portion 222 is formed integrally with the sub ridge portion 212. The protruding ridge portion 222 corresponds to the protrusion 48 of the first embodiment.

The width of the protruding ridge portion 222 is greater than the width of the main ridge portion 202. The width of the protruding ridge portion 222 is greater than the width of the intermediate ridge portion 218. The width of the protruding ridge portion 222 is smaller than the width of the end ridge portion 208. The width of the protruding ridge portion 222 is defined by the dimension of the distal end portion of the protruding ridge portion 222 in the Y-axis direction.

The fifth extension portion 224 extends from the protruding ridge portion 222 in conformance with the shape of the protruding ridge portion 222 in plan view. Therefore, in other words, the fifth extension portion 224 includes the two side surfaces 48A, the distal end surface 48B, and the two connection portions 48C. The fifth extension portion 224 extends longer than the first extension portion 204 toward the outside of the protruding ridge portion 222 in plan view. In one example, the length of the fifth extension portion 224 is equal to the length of the second extension portion 206. The length of the fifth extension portion 224 may be greater than the length of the second extension portion 206.

The fifth extension portion 224 has a smaller thickness than the protruding ridge portion 222. The fifth extension portion 224 may have different thicknesses at different positions. In one example, the fifth extension portion 224 includes a tapered portion having a thickness that gradually decreases as the distance from the protruding ridge portion 222 increases in a region adjacent to the protruding ridge portion 222, and a flat portion having a substantially constant thickness in a region located away from the protruding ridge portion 222 by a predetermined distance or more. Alternatively, the fifth extension portion 224 may include only a flat portion or may include only a tapered portion. The fifth extension portion 224 can have a thickness of 5 nm or more and 100 nm or less. The flat portion of the fifth extension portion 224 excluding the tapered portion may have a thickness of 10 nm or more and 30 nm or less. In one example, the flat portion of the fifth extension portion 224 has a thickness of about 15 nm.

The fifth extension portion 224 connects the fourth extension portion 216 connected to the second extension portion 206 of the main gate portion 44A and the fourth extension portion 216 connected to the second extension portion 206 of the main gate portion 44B. The fifth extension portion 224 is formed continuously with the fourth extension portion 216 in the first inactive region 104. In one example, the fifth extension portion 224 is formed integrally with the fourth extension portion 216.

### Effects

According to the nitride semiconductor device 200 of the present embodiment, the following effects may be obtained in addition to the effects of the first embodiment.

(2-1) The main gate portion 44A includes a main ridge portion 202 where the gate electrode 24 is located, a first extension portion 204 extending from the main ridge portion 202 toward the source opening 26AA, and a second extension portion 206 extending from the main ridge portion 202 toward the drain opening 26BA.

According to this configuration, when application of a positive bias to the gate electrode 24 causes holes to enter the gate layer 22 from the gate electrode 24, the holes are dispersed in the first extension portion 204 and the second extension portion 206. Therefore, the density of holes in the interface between the gate layer 22 and the electron supply layer 18 is reduced as compared with a configuration that does not include the extension portions 204 and 206. This limits band bending of the electron supply layer 18 due to hole accumulation, thereby restricting movement of electrons from the electron transit layer 16 to the gate layer 22, that is, a gate leakage current. The main gate portion 44B has the same configuration as the main gate portion 44A. Therefore, the same effect may be obtained in the main gate portion 44B.

(2-2) The sub gate portion 46 includes a sub ridge portion 212 in which the gate electrode 24 is located, a third extension portion 214 extending from the sub ridge portion 212 toward the source opening 26AA, and a fourth extension portion 216 extending from the sub ridge portion 212 toward the drain opening 26BA. The gate electrode 24 is located on the sub ridge portion 212. The protrusion 48 includes a protruding ridge portion 222 protruding from the sub ridge portion 212 toward the drain opening 26BA in the X-axis direction, and a fifth extension portion 224 extending from the protruding ridge portion 222 in conformance with the shape of the protruding ridge portion 222 in plan view. The third extension portion 214 is formed continuously with the first extension portion 204. The fourth extension portion 216 is formed continuously with the second extension portion 206. The fifth extension portion 224 is formed continuously with the fourth extension portion 216.

According to this configuration, similarly to the effect of (2-1), formation of the extension portions 214, 216, and 224 reduces a gate leakage current from the electron transit layer 16 to the gate layer 22 in the sub gate portion 46 and the protrusion 48.

### Modified Example

Each of the above embodiments may be modified as follows. In addition, each of the above embodiments and each of the following modified examples may be implemented in combination with each other within a range not technically contradictory.

### Modified Example of Source Electrode

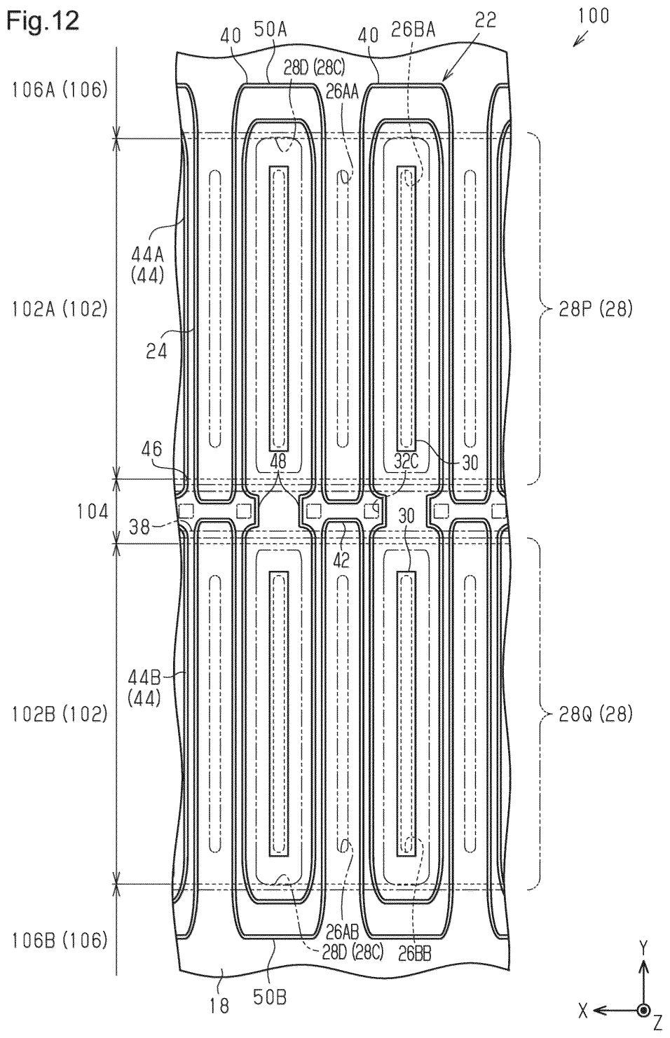

In each embodiment, the shape of the source electrode 28 in plan view may be changed in any manner. In one example, as shown in FIG. 12, the source electrode 28 may be separated in the Y-axis direction via the first inactive region 104 in plan view. That is, the source electrode 28 includes a first source electrode 28P and a second source electrode 28Q disposed separately in the Y-axis direction.

The first source electrode 28P is formed over the first active region 102A, a part of the second inactive region 106A adjacent to the first active region 102A, and a part of the first inactive region 104 in plan view. The first source electrode 28P is disposed closer to the first active region 102A than the gate wiring opening 32C.

The second source electrode 28Q is formed over the second active region 102B, a part of the second inactive region 106B adjacent to the second active region 102B, and a part of the first inactive region 104 in plan view. The second source electrode 28Q is disposed closer to the second active region 102B than the gate wiring opening 32C.

As described above, the first inactive region 104 includes a region where the source electrode 28 is not formed. The interlayer insulating layer 32 and the source wiring 34 are disposed in this region. Therefore, as compared with a configuration in which the source electrode 28 is disposed in the first inactive region 104, the distance between the gate wiring 38 (refer to FIG. 2) disposed in the first inactive region 104 and the source electrode 28 is increased. This reduces the parasitic capacitance between the gate wiring 38 and the source electrode 28.

The dimension of each of the first source electrode 28P and the second source electrode 28Q in the Y-axis direction may be changed in any manner. In one example, the first source electrode 28P may not be formed in the first inactive region 104 in plan view. That is, the first source electrode 28P may be formed over the first active region 102A and a part of the second inactive region 106A. In addition, the second source electrode 28Q may not be formed in the first inactive region 104 in plan view. That is, the second source electrode 28Q may be formed over the second active region 102B and a part of the second inactive region 106B.

### Modified Example of Source Opening

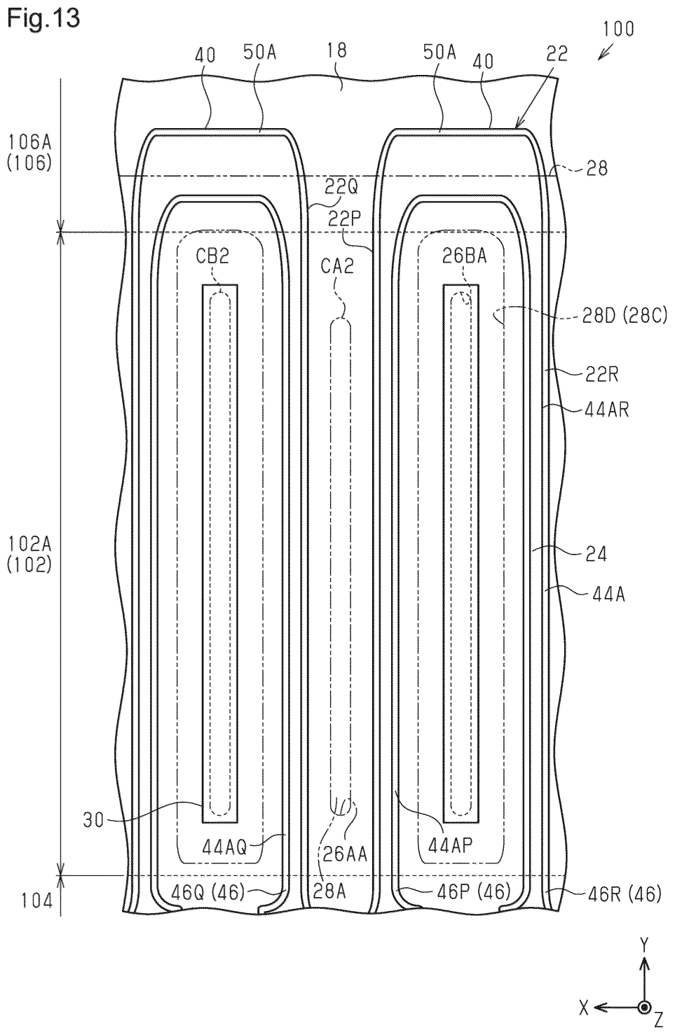

In each embodiment, the position of the second end portion CA2, which is one of the two end portions of the source opening 26AA (26AB) in the Y-axis direction located closer to the second inactive region 106A (106B), may be changed in any manner. In one example, as shown in FIG. 13, the second end portion CA2 of the source opening 26AA is disposed closer to the first inactive region 104 than the second end portion CB2 of the drain opening 26BA is. In other words, the second end portion CA2 of the source opening 26AA is disposed farther away from the second inactive region 106A than the second end portion CB2 of the drain opening 26BA is.

This configuration increases the distance between the second connection portion 50A of the gate layer 22 and the source contact portion 28A filling the source opening 26AA. This increases the distance between the gate electrode 24 formed on the second connection portion 50A and the source contact portion 28A in plan view. Thus, a gate leakage current transmitted through the surface of the electron supply layer 18 between the gate electrode 24 and the source electrode 28 is reduced.

In the same manner, the second end portion CA2 of the source opening 26AB may be disposed closer to the first inactive region 104 than the second end portion CB2 of the drain opening 26BB is. This configuration also reduces a gate leakage current transmitted through the surface of the electron supply layer 18 between the gate electrode 24 and the source electrode 28.

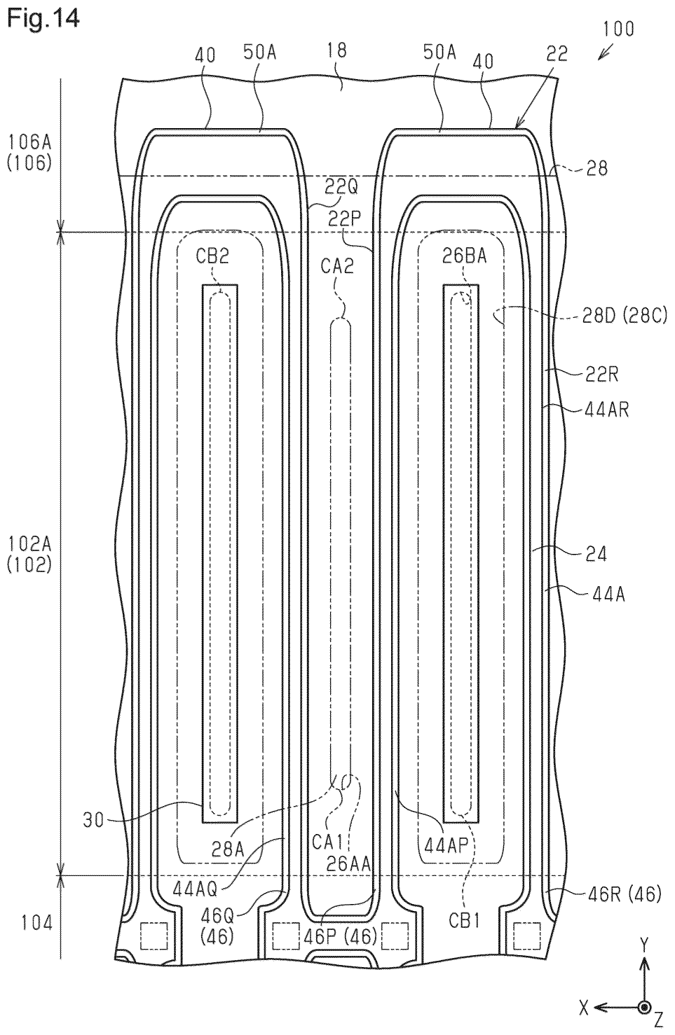

In each embodiment, the position of the first end portion CA1, which is one of the two end portions of the source opening 26A in the Y-axis direction located closer to the first inactive region 104, may be changed in any manner. In one example, as shown in FIG. 14, the first end portion CA1 of the source opening 26AA is disposed farther away from the first inactive region 104 than the first end portion CB1 of drain opening 26BA is.

This configuration increases the distance between the first connection portion 42 of the gate layer 22 and the source contact portion 28A filling the source opening 26AA. This increases the distance between the gate electrode 24 formed on the first connection portion 42 and the source contact portion 28A in plan view. This configuration reduces a gate leakage current transmitted through the surface of the electron supply layer 18 between the gate electrode 24 and the source electrode 28.

As shown in FIG. 14, the first end portion CA1 of the source opening 26AA may be disposed at a position farther away from the first inactive region 104 than the first end portion CB1 of the drain opening 26BA is, and the second end portion CA2 of the source opening 26AA may be disposed at a position farther away from the second inactive region 106A than the second end portion CB2 of the drain opening 26BA is. This configuration increases both the distance between the source contact portion 28A and the second connection portion 50A and the distance between the source contact portion 28A and the first connection portion 42. Thus, the gate leakage current transmitted through the surface of the electron supply layer 18 between the gate electrode 24 and the source electrode 28 is reduced more effectively.

In the same manner, the first end portion CA1 of the source opening 26AB may be disposed at a position farther away from the first inactive region 104 than the first end portion CB1 of the drain opening 26BB is. This configuration also reduces the gate leakage current transmitted through the surface of the electron supply layer 18 between the gate electrode 24 and the source electrode 28.

### Modified Example of Active Region and Inactive Region

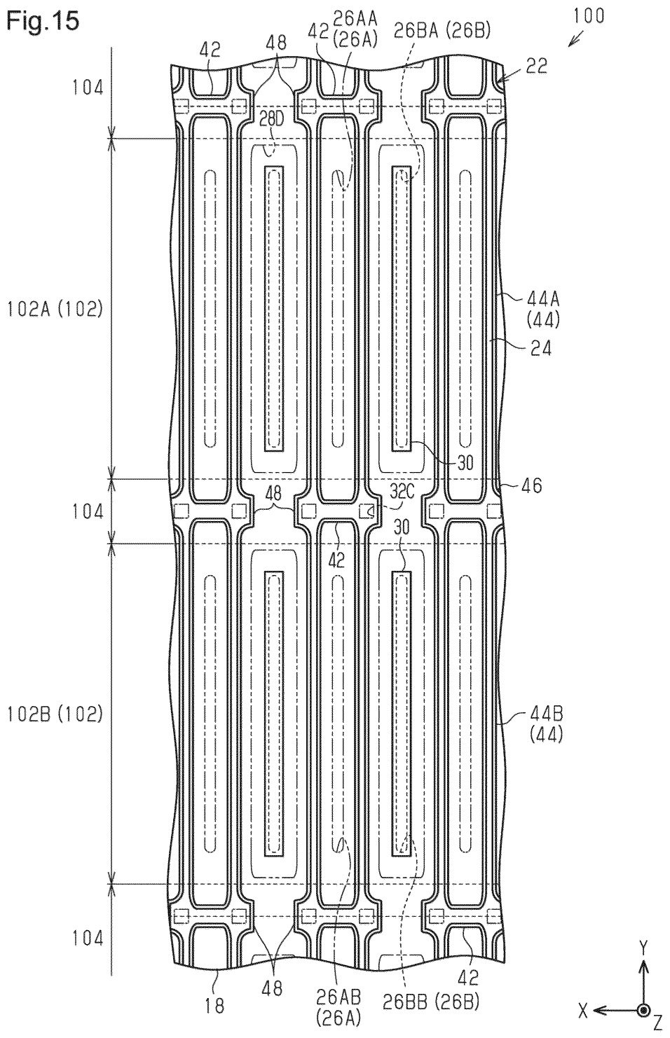

In each embodiment, the number of the first inactive regions 104 may be changed in any manner. The formation patterns 100 and 300 may include a plurality of first inactive regions 104. In one example, as shown in FIG. 15, in the formation pattern 100, the plurality of first inactive regions 104 may be separated from each other via the source opening 26A and the drain opening 26B in the Y-axis direction. That is, the formation pattern 100 may include three or more active regions 102.

In each embodiment, the positions of the boundary lines LB1 to LB4 between the active region 102 and the first inactive region 104 and between the active region 102 and the second inactive region 106 in the Y-axis direction may be changed in any manner. In one example, the boundary line LB1 between the first active region 102A and the first inactive region 104 may be aligned in the Y-axis direction with one of the two edges of the drain opening 26B in the Y-axis direction located closer to the first active region 102A. The boundary line LB2 may be changed in the same manner as the boundary line LB1. In one example, the boundary line LB3 between the first active region 102A and the first inactive region 104 may be aligned in the Y-axis direction with one of the two edges of the drain opening 26B in the Y-axis direction located closer to the second active region 102B. The boundary line LB4 may be changed in the same manner as the boundary line LB3.

### Modified Example of Protrusion

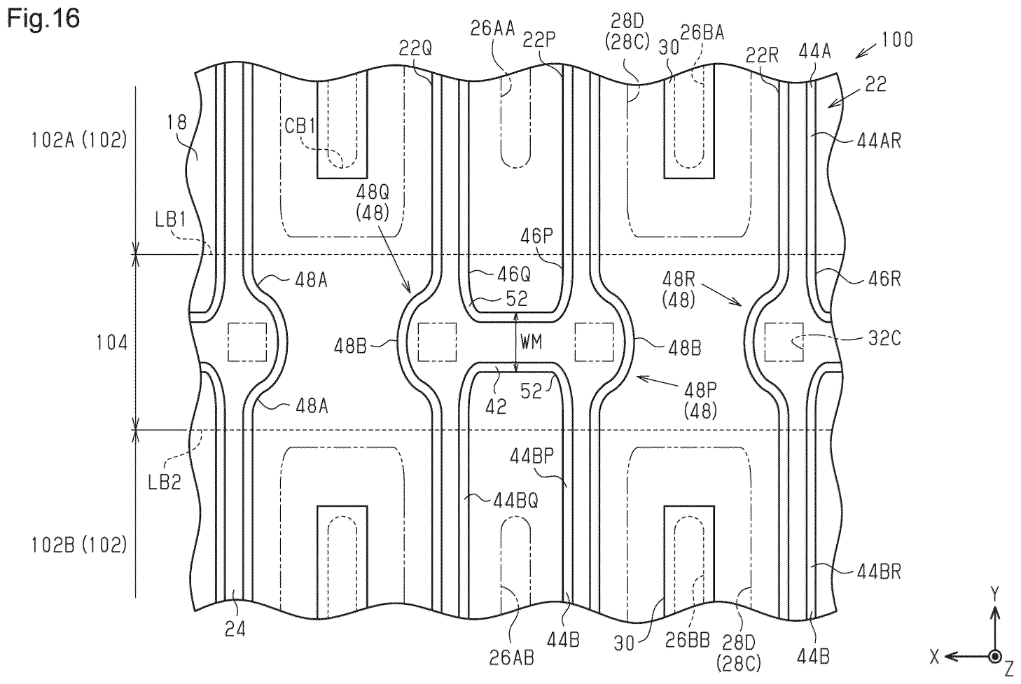

In each embodiment, the shape of the protrusion 48 in plan view may be changed in any manner. In one example, as shown in FIG. 16, the distal end surface 48B of the protrusion 48 may be formed so as to have a convex shape projecting toward the protrusion 48 facing in the X-axis direction.

In each embodiment, the width WP of the protrusion 48 may be changed in any manner. In one example, the width WP of the protrusion 48 may be equal to the width WM of the first connection portion 42. The width WP of the protrusion 48 may be smaller than the width WM of the first connection portion 42. In one example, the width WP of the protrusion 48 may be equal to the width WE of the second connection portion 50A. The width WP of the protrusion 48 may be greater than the width WE of the second connection portion 50A. In one example, the width WP of the protrusion 48 may be equal to the width WG of the main gate portion 44. The width WP of the protrusion 48 may be smaller than the width WG of the main gate portion 44.

In each embodiment, the position of the distal end surface 48B of the protrusion 48 may be changed in any manner. In one example, the distal end surface 48B of the protrusion 48 may be located closer to the drain opening 26BA in the X-axis direction than the central position between the main gate portion 44 and the drain opening 26BA in the X-axis direction. The protrusion length LX of the protrusion 48 from the sub gate portion 46 may be greater than or equal to ½ of a distance DX between the sub gate portion 46 and the drain opening 26BA in the X-axis direction.

In each embodiment, the protrusion 48 may be omitted from a sub gate portion 46. In this case, the gate wiring opening 32C is not formed in the sub gate portion 46 that does not include the protrusion 48.

### Modified Example of Gate Wiring Opening

In each embodiment, the shape of the gate wiring opening 32C in plan view may be changed in any manner. In one example, the shape of the gate wiring opening 32C in plan view may be circular. In one example, the shape of the gate wiring opening 32C in plan view may be rectangular so that the long sides extend in the X-axis direction and the short sides extend in the Y-axis direction.

In each embodiment, the position of the gate wiring opening 32C may be changed in any manner. In one example, the gate wiring opening 32C may be disposed at a position overlapping the first connection portion 42 of the gate layer 22 in plan view. In one example, the gate wiring opening 32C may be disposed at a position overlapping the protrusion 48 and not overlapping the sub gate portion 46 in plan view. In one example, the gate wiring opening 32C may be formed at a position overlapping the sub gate portion 46 and not overlapping the protrusion 48 in plan view.

### Modified Example of Gate Layer

In the second embodiment, the configuration of the main gate portion 44A of the gate layer 22 may be changed in any manner. In one example, the main gate portion 44A may include the main ridge portion 202 and only one of the first extension portion 204 and the second extension portion 206. For example, the main gate portion 44A may include the main ridge portion 202 and the first extension portion 204 without including the second extension portion 206. For example, the main gate portion 44A may include the main ridge portion 202 and the second extension portion 206 without including the first extension portion 204. The main gate portion 44B may be changed in the same manner.

In the second embodiment, the configuration of the second connection portion 50A of the gate layer 22 may be changed in any manner. In one example, the second connection portion 50A may include the end ridge portion 208 and only one of the two end extension portions 210A and 210B. In one example, the two end extension portions 210A and 210B may be omitted from the second connection portion 50A. The second connection portion 50B may be changed in the same manner.

In the second embodiment, the configuration of the first connection portion 42 of the gate layer 22 may be changed in any manner. In one example, the first connection portion 42 may include the intermediate ridge portion 218 and only one of the two intermediate extension portions 220A and 220B. In one example, the two intermediate extension portions 220A and 220B may be omitted from the first connection portion 42.

In the second embodiment, the configuration of the sub gate portion 46 of the gate layer 22 may be changed in any manner. In one example, the sub gate portion 46 may include the sub ridge portion 212 and only one of the third extension portion 214 and the fourth extension portion 216. For example, the sub gate portion 46 may include the sub ridge portion 212 and the third extension portion 214 without including the fourth extension portion 216. For example, the sub gate portion 46 may include the sub ridge portion 212 and the fourth extension portion 216 without including the third extension portion 214. For example, the third extension portion 214 and the fourth extension portion 216 may be omitted from the sub gate portion 46.

In the second embodiment, the configuration of the protrusion 48 of the gate layer 22 may be changed in any manner. In one example, the fifth extension portion 224 may be omitted from the protrusion 48.

In the second embodiment, the length of the fifth extension portion 224 from the protruding ridge portion 222 may be changed in any manner. In one example, a length of a portion of the fifth extension portion 224 corresponding to the distal end surface 48B of the protrusion 48 from the protruding ridge portion 222 is greater than a length of a portion of the fifth extension portion 224 corresponding to the two side surfaces 48A of the protrusion 48 from the protruding ridge portion 222. In addition, in one example, the length of the fifth extension portion 224 from the protruding ridge portion 222 is greater than the length of the fourth extension portion 216 from the sub ridge portion 212.

In the second embodiment, an extension portion extending from the ridge portion toward the source opening or the drain opening may be formed in at least a part of the ridge portion of the gate layer 22 where the gate electrode 24 is located.

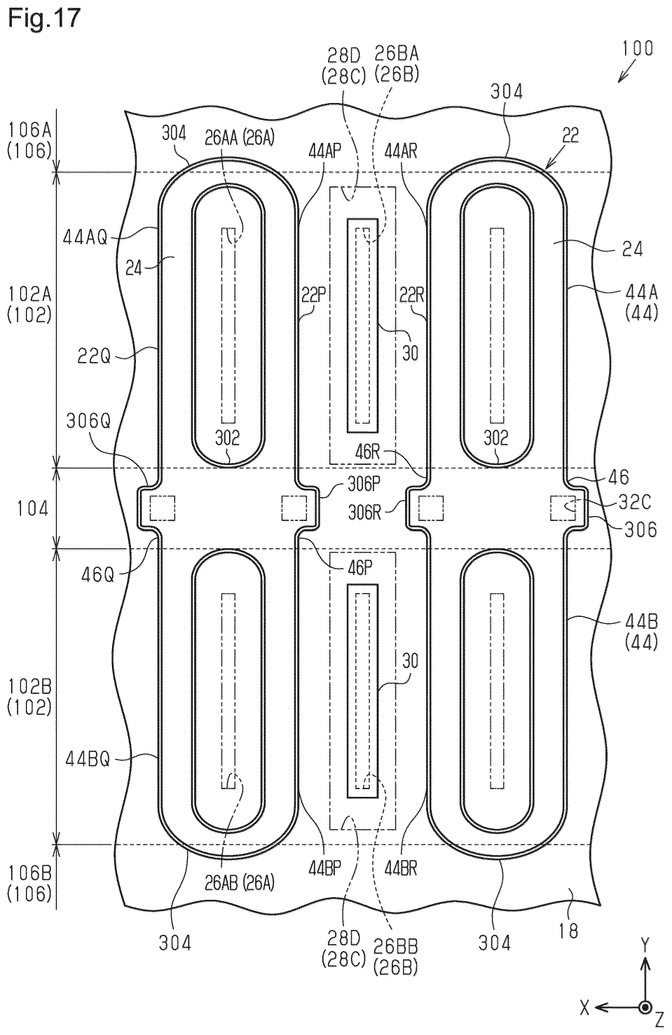

In each embodiment, the shape of the gate layer 22 in plan view may be changed in any manner. In one example, as shown in FIG. 17, the gate layer 22 includes a first connection portion 302 formed in the first inactive region 104 and a second connection portion 304 formed in the second inactive region 106A (106B). More specifically, the first connection portion 302 connects the first sub gate portion 46P of the first gate layer 22P and the third sub gate portion 46R of the third gate layer 22R disposed at opposite sides of the source opening 26A in the X-axis direction. The second connection portion 304 connects the first main gate portion 44AP of the first gate layer 22P and the third main gate portion 44AR of the third gate layer 22R in the second inactive regions 106A and 106B. The source opening 26AA is surrounded by the first main gate portion 44AP of the first gate layer 22P, the third main gate portion 44AR of the third gate layer 22R, the first connection portion 302, and the second connection portion 304. Also, the source opening 26AB is surrounded by the first main gate portion 44BP of the first gate layer 22P, the third main gate portion 44BR of the third gate layer 22R, the first connection portion 302, and the second connection portion 304.

The gate layer 22 includes a protrusion 306 that protrudes from the sub gate portion 46 toward the drain opening 26B in the X-axis direction in the first inactive region 104. More specifically, the first gate layer 22P includes the first protrusion 306P as the protrusion 306, the second gate layer 22Q includes the second protrusion 306Q as the protrusion 306, and the third gate layer 22R includes the third protrusion 306R as the protrusion 306. The protrusion 306 is aligned with the first connection portion 302 in the Y-axis direction. In one example, the protrusion 306 has the same shape as the protrusion 48 (refer to FIG. 4) of each embodiment.

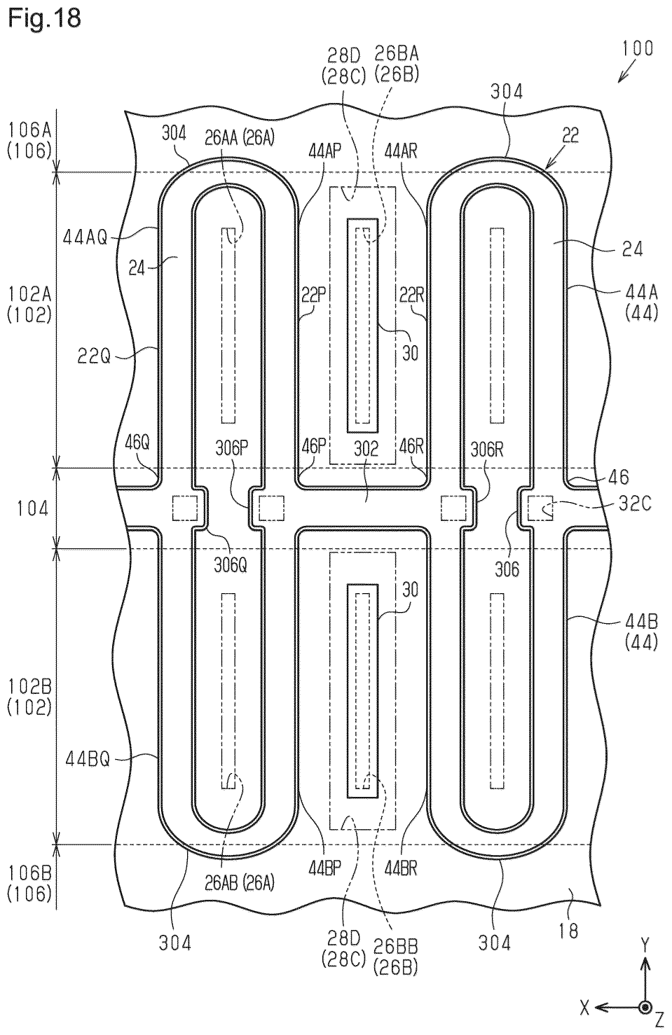

In the modified example shown in FIG. 17, the configuration of the first connection portion 302 may be changed in any manner. In one example, as shown in FIG. 18, the first connection portion 302 may connect the first main gate portion 44AP of first gate layer 22P and the second main gate portion 44AQ of the second gate layer 22Q. Thus, the drain opening 26BA is surrounded by the first main gate portion 44AP of the first gate layer 22P, the second main gate portion 44AQ of the second gate layer 22Q, and the first connection portion 302. The first connection portion 302 may connect the first main gate portion 44BP of the first gate layer 22P and the second main gate portion 44BQ of the second gate layer 22Q. Thus, the drain opening 26BB is surrounded by the first main gate portion 44BP of the first gate layer 22P, the second main gate portion 44BQ of the second gate layer 22Q, and the first connection portion 302. In addition, the source opening 26AA is surrounded by the first main gate portion 44AP of the first gate layer 22P, the second main gate portion 44AQ of the second gate layer 22Q, and the second connection portion 304. The source opening 26AB is surrounded by the first main gate portion 44BP of the first gate layer 22P, the second main gate portion 44BQ of the second gate layer 22Q, and the second connection portion 304. In this case, the protrusion 306 protrudes from the gate layer 22 toward the source opening 26A in the X-axis direction. More specifically, the first protrusion 306P protrudes from the first sub gate portion 46P toward the source opening 26AA. The second protrusion 306Q protrudes from the second sub gate portion 46Q toward the source opening 26AA. The third protrusion 306R protrudes from the third sub gate portion 46R toward the source opening 26AA.

The term “on” as used in the present disclosure includes the meaning of “on” and “above” unless the context clearly dictates otherwise. Thus, the expression “a first layer is formed on a second layer” is intended such that the first layer may be disposed directly on the second layer in contact with the second layer in some embodiments, while the first layer may be disposed above the second layer without contacting the second layer in other embodiments. That is, the term “on” does not exclude structures in which other layers are formed between the first and second layers. For example, the above-described embodiment in which the electron supply layer 18 is formed on the electron transit layer 16 also includes a structure in which an intermediate layer is located between the electron supply layer 18 and the electron transit layer 16 in order to stably form the 2DEG20.

The Z-axis direction used in the present disclosure does not necessarily need to be the vertical direction, and does not need to completely coincide with the vertical direction. Therefore, various structures (for example, the structure shown in FIG. 1) according to the present disclosure are not limited to the fact that “above” and “below” in the Z-axis direction described herein are “above” and “below” in the vertical direction. For example, the X-axis direction may be the vertical direction, or the Y-axis direction may be the vertical direction.

“At least one of A and B” used in the present disclosure should be understood as meaning “only A, or only B, or both A and B”.

### Clauses

Technical ideas that may be grasped from the above embodiments and modified examples will be described below. For the purpose of not limiting but assisting understanding, corresponding reference signs in the embodiments are shown in parentheses for the configurations described in the supplementary notes. The reference signs are given as examples to aid understanding, and the components described in each reference sign should not be limited to the components indicated by the reference signs.

### [Clause 1]

A nitride semiconductor device (10), including:
an electron supply layer (18) including a nitride semiconductor;
a gate layer (22) formed on a part of the electron supply layer (18), the gate layer including a nitride semiconductor having an acceptor impurity;
a gate electrode (24) formed on the gate layer (22);
a passivation layer (26) covering the electron supply layer (18), the gate layer (22), and the gate electrode (24) and having a source opening (26A) and a drain opening (26B) disposed at opposite sides of the gate layer (22) in a first direction (X-axis direction) in plan view;
a source electrode (28) in contact with the electron supply layer (18) exposed by the source opening (26A);
a drain electrode (30) in contact with the electron supply layer (18) exposed by the drain opening (26B);
an active region (102) extending in the first direction (X-axis direction) and including the source opening (26A) and the drain opening (26B); and
an inactive region (104) adjacent to the active region (102) in a second direction (Y-axis direction) orthogonal to the first direction (X-axis direction) in plan view,
in which the gate layer (22) includes:
a main gate portion (44) extending in the second direction in the active region (102);
a sub gate portion (46) extending in the second direction (Y-axis direction) so as to be continuous with the main gate portion (44) in the inactive region (104); and
a protrusion (48) protruding from the sub gate portion (46) toward the drain opening (26B) in the first direction (X-axis direction).

### [Clause 2]

The nitride semiconductor device according to clause 1, in which a distal end of the protrusion (48) in the first direction (X-axis direction) is located closer to the sub gate portion (46) than a central position between the sub gate portion (46) and the drain opening (26B) in the first direction (X-axis direction).

### [Clause 3]

The nitride semiconductor device according to clause 1 or 2, further including:
an interlayer insulating layer (32) covering the source electrode (28) and the passivation layer (26), in which
a gate opening (32C) is formed in both the interlayer insulating layer (32) and the passivation layer (26) to expose the gate electrode (24), and
the gate opening (32C) extends over both the protrusion (48) and the sub gate portion (46) in the first direction (X-axis direction) in plan view.

### [Clause 4]

The nitride semiconductor device according to any one of clauses 1 to 3,
in which a width (WP) of the protrusion (48) in the second direction (Y-axis direction) is greater than a width (WG) of the main gate portion (44) in the first direction (X-axis direction).

### [Clause 5]

The nitride semiconductor device according to any one of clauses 1 to 4, in which both the main gate portion (44) and the sub gate portion (46) are disposed closer to the source opening (26A) than to the drain opening (26B) in the first direction (X-axis direction).

### [Clause 6]

The nitride semiconductor device according to any one of clauses 1 to 5, in which a distance between the protrusion (48) and an end portion (CB1) of the drain opening (26B) in the second direction (Y-axis direction) is greater than or equal to a distance between the drain opening (26B) and the main gate portion (44) in the first direction (X-axis direction).

### [Clause 7]

The nitride semiconductor device according to any one of clauses 1 to 6, in which the gate layer (22) includes:
a first gate layer (22P) including a first main gate portion (44AP) as the main gate portion (44), a first sub gate portion (46P) as the sub gate portion (46), and a first protrusion (48P) as the protrusion (48);
a second gate layer (22Q) separated from the first gate layer (22P) in the first direction (X-axis direction) via the source opening (26A) in plan view, the second gate layer (22Q) including a second main gate portion (44AQ) as the main gate portion (44), a second sub gate portion (46Q) as the sub gate portion (46), and a second protrusion (48Q) as the protrusion (48); and
a first connection portion (42) that connects the first sub gate portion (46P) and the second sub gate portion (46Q) in the inactive region (104),
the two protrusions (48P, 48Q) are located at a side of the two sub gate portions (46P, 46Q), respectively, the side being opposite to the first connection portion (42) in the first direction (X-axis direction), and
the source opening (26A) is surrounded by the first main gate portion (44AP), the second main gate portion (44AQ), and the first connection portion (42).

### [Clause 8]

The nitride semiconductor device according to clause 7, in which a width (WM) of the first connection portion (42) in the second direction (Y-axis direction) is smaller than a width (WP) of the protrusion (48) in the second direction (Y-axis direction).

### [Clause 9]

The nitride semiconductor device according to clause 7 or 8, including:
a first inactive region (104) as the inactive region; and
a second inactive region (106A) formed at a side opposite to the first inactive region (104) with respect to the active region (102) in the second direction (Y-axis direction), in which
the gate layer (22) includes:
a third gate layer (22R) separated from the first gate layer (22P) in the first direction (X-axis direction) via the drain opening (26B) in plan view, the third gate layer (22R) including a third main gate portion (44AR) as the main gate portion (44); and
a second connection portion (50A) that connects the first main gate portion (44AP) and the third main gate portion (44AR) in the second inactive region (106A), and
the drain opening (26B) is surrounded by the first main gate portion (44AP), the third main gate portion (44AR), and the second connection portion (50A).

### [Clause 10]

The nitride semiconductor device according to clause 9, in which a width (WE) of the second connection portion (50A) in the second direction (Y-axis direction) is greater than a width (WG) of the main gate portion (44) in the first direction (X-axis direction).

### [Clause 11]

The nitride semiconductor device according to clause 9 or 10, in which an end portion (CA2) of the source opening (26A), the end portion (CA2) being one of two end portions of the source opening (26A) in the second direction (Y-axis direction) that is located closer to the second inactive region (106A), is disposed closer to the first inactive region (104) than an end portion (CB2) of the drain opening (26B), the end portion (CB2) being one of two end portions of the drain opening (26B) in the second direction (Y-axis direction) that is located closer to the second inactive region (106A).

### [Clause 12]

The nitride semiconductor device according to any one of clauses 9 to 11, in which an end portion (CA1) of the source opening (26A), the end portion (CA1) being one of two end portions of the source opening (26A) in the second direction (Y-axis direction) that is located closer to the first inactive region (104), is located so as to be farther way from the first inactive region (104) than an end portion (CB1) of the drain opening (26B), the end portion (CB1) being one of two end portions of the drain opening (26B) in the second direction (Y-axis direction) that is located closer to the first inactive region (104).

### [Clause 13]

The nitride semiconductor device according to any one of clauses 1 to 12, in which the source electrode includes source electrodes (28P, 28Q) separated in the second direction (Y-axis direction) in the inactive region (104) in plan view.

### [Clause 14]

The nitride semiconductor device according to any one of clauses 1 to 13, in which the main gate portion (44) includes:
a main ridge portion (202) on which the gate electrode (24) is located;
a first extension portion (204) extending from the main ridge portion (202) toward the source opening (26A); and
a second extension portion (206) extending from the main ridge portion (202) toward the drain opening (26B).

### [Clause 15]

The nitride semiconductor device according to clause 14, in which
the sub gate portion (46) includes:
a sub ridge portion (212) formed continuously with the main ridge portion (202), the gate electrode (24) being disposed on the sub ridge portion (212);
a third extension portion (214) extending from the sub ridge portion (212) toward the source opening (26A); and
a fourth extension portion (216) extending from the sub ridge portion (212) toward the drain opening (26B), and
the protrusion (48) includes:
a protruding ridge portion (222) protruding from the sub ridge portion (212) toward the drain opening (26B) in the first direction (X-axis direction); and
a fifth extension portion (224) extending from the protruding ridge portion (222) in conformance with a shape of the protruding ridge portion (222) in plan view, and
the third extension portion (214) is formed continuously with the first extension portion (204),
the fourth extension portion (216) is formed continuously with the second extension portion (206), and
the fifth extension portion (224) is formed continuously with the fourth extension portion (216).

### [Clause 16]

The nitride semiconductor device according to any one of clauses 1 to 15, in which
the electron supply layer (18) is an AlₓGa₁₋ₓN layer, where 0.1<x<0.3, and
the acceptor impurity contains at least one of Mg and Zn.

### [Clause 17]

A nitride semiconductor device (10), including:
an electron supply layer (18) including a nitride semiconductor;
a gate layer (22) formed on a part of the electron supply layer (18), the gate layer (22) including a nitride semiconductor having an acceptor impurity;
a gate electrode (24) formed on the gate layer (22);
a passivation layer (26) covering the electron supply layer (18), the gate layer (22), and the gate electrode (24) and having a source opening (26A) and a drain opening (26B) disposed at opposite sides of the gate layer (22) in a first direction (X-axis direction) in plan view;
a source electrode (28) in contact with the electron supply layer (18) exposed by the source opening (26A);
a drain electrode (30) in contact with the electron supply layer (18) exposed by the drain opening (26B);
an active region (102) extending in the first direction (X-axis direction) and including the source opening (26A) and the drain opening (26B); and
an inactive region (104) adjacent to the active region (102) in a second direction (Y-axis direction) orthogonal to the first direction (X-axis direction) in plan view, in which
the gate layer (22) includes:
a main gate portion (44) extending in the second direction (Y-axis direction) in the active region (102);
a sub gate portion (46) extending in the second direction (Y-axis direction) so as to be continuous with the main gate portion (44) in the inactive region (104); and
a protrusion (306) protruding from the sub gate portion (46) toward the source opening (26A) in the first direction (X-axis direction).

### [Clause 18]

The nitride semiconductor device according to clause 17, in which
the gate layer (22) includes:
a first gate layer (22P) including a first main gate portion (44AP) as the main gate portion (44), a first sub gate portion (46P) as the sub gate portion (46), and a first protrusion (306P) as the protrusion (306);
a third gate layer (22R) separated from the first gate layer (22P) in the first direction (X-axis direction) via the drain opening (26B) in plan view and including a third main gate portion (44AR) as the main gate portion (44), a third sub gate portion (46R) as the sub gate portion (46), and a third protrusion (306R) as the protrusion (306); and
a first connection portion (302) that connects the first sub gate portion (46P) and the third sub gate portion (46R) in the inactive region (104),
the two protrusions (306P, 306R) are disposed at a side of the two sub gate portions (46P, 46R), respectively, opposite to the first connection portion (302) in the first direction, and
the drain opening (26B) is surrounded by the first main gate portion (44AP), the third main gate portion (44AR), and the first connection portion (302).

### [Clause 19]

The nitride semiconductor device according to clause 17 or 18, in which
the inactive region includes a first inactive region (104), and a second inactive region (106A) formed at a side opposite to the first inactive region (104) with respect to the active region (102) in the second direction (Y-axis direction), and
the gate layer (22) includes:
a second connection portion (304) that connects the first main gate portion (44AP) and the third main gate portion (44AR) in the second inactive region (106A), and
the drain opening (26B) is surrounded by the first main gate portion (44AP), the third main gate portion (44AR), and the second connection portion (304).

The above description is merely exemplary. Those skilled in the art will recognize that more conceivable combinations and permutations are possible other than the components and methods (production processes) listed for the purpose of describing the technology of the present disclosure. The present disclosure is intended to cover all alternatives, variations, and modified examples falling within the scope of the present disclosure, including the claims.

1. A nitride semiconductor device, comprising:
an electron supply layer including a nitride semiconductor;
a gate layer formed on a part of the electron supply layer, the gate layer including a nitride semiconductor having an acceptor impurity;
a gate electrode formed on the gate layer;
a passivation layer covering the electron supply layer, the gate layer, and the gate electrode and having a source opening and a drain opening disposed at opposite sides of the gate layer in a first direction in plan view;
a source electrode in contact with the electron supply layer exposed by the source opening;
a drain electrode in contact with the electron supply layer exposed by the drain opening;
an active region extending in the first direction and including the source opening and the drain opening; and
an inactive region adjacent to the active region in a second direction orthogonal to the first direction in plan view,
wherein the gate layer includes:
a main gate portion extending in the second direction in the active region;
a sub gate portion extending in the second direction so as to be continuous with the main gate portion in the inactive region; and
a protrusion protruding from the sub gate portion toward the drain opening in the first direction.

2. The nitride semiconductor device according to claim 1, wherein a distal end of the protrusion in the first direction is located closer to the sub gate portion than a central position between the sub gate portion and the drain opening in the first direction.

3. The nitride semiconductor device according to claim 1, further comprising:
an interlayer insulating layer covering the source electrode and the passivation layer, wherein
a gate opening is formed in both the interlayer insulating layer and the passivation layer to expose the gate electrode, and
the gate opening extends over both the protrusion and the sub gate portion in the first direction in plan view.

4. The nitride semiconductor device according to claim 1,
wherein a width of the protrusion in the second direction is greater than a width of the main gate portion in the first direction.

5. The nitride semiconductor device according to claim 1, wherein both the main gate portion and the sub gate portion are disposed closer to the source opening than to the drain opening in the first direction.

6. The nitride semiconductor device according to claim 1, wherein a distance between the protrusion and an end portion of the drain opening in the second direction is greater than or equal to a distance between the drain opening and the main gate portion in the first direction.

7. The nitride semiconductor device according to claim 1, wherein
the gate layer includes:
a first gate layer including a first main gate portion as the main gate portion, a first sub gate portion as the sub gate portion, and a first protrusion as the protrusion;
a second gate layer separated from the first gate layer in the first direction via the source opening in plan view, the second gate layer including a second main gate portion as the main gate portion, a second sub gate portion as the sub gate portion, and a second protrusion as the protrusion; and
a first connection portion that connects the first sub gate portion and the second sub gate portion in the inactive region,
the two protrusions are disposed at a side of the two sub gate portions, respectively, the side being opposite to the first connection portion in the first direction, and
the source opening is surrounded by the first main gate portion, the second main gate portion, and the first connection portion.

8. The nitride semiconductor device according to claim 7, wherein a width of the first connection portion in the second direction is smaller than a width of the protrusion in the second direction.

9. The nitride semiconductor device according to claim 7, comprising:
a first inactive region as the inactive region; and
a second inactive region formed at a side opposite to the first inactive region with respect to the active region in the second direction, wherein
the gate layer includes:
a third gate layer separated from the first gate layer in the first direction via the drain opening in plan view, the third gate layer including a third main gate portion as the main gate portion; and
a second connection portion that connects the first main gate portion and the third main gate portion in the second inactive region, and
the drain opening is surrounded by the first main gate portion, the third main gate portion, and the second connection portion.

10. The nitride semiconductor device according to claim 9, wherein a width of the second connection portion in the second direction is greater than a width of the main gate portion in the first direction.

11. The nitride semiconductor device according to claim 9, wherein an end portion of the source opening, the end portion being one of two end portions of the source opening in the second direction that is located closer to the second inactive region, is disposed closer to the first inactive region than an end portion of the drain opening, the end portion being one of two end portions of the drain opening in the second direction that is located closer to the second inactive region.

12. The nitride semiconductor device according to claim 9, wherein an end portion of the source opening, the end portion being one of two end portions of the source opening in the second direction that is located closer to the first inactive region, is located so as to be farther away from the first inactive region than an end portion of the drain opening, the end portion being one of two end portions of the drain opening in the second direction that is located closer to the first inactive region.

13. The nitride semiconductor device according to claim 1, wherein the source electrode includes source electrodes separated in the second direction in the inactive region in plan view.

14. The nitride semiconductor device according to claim 1, wherein the main gate portion includes:
a main ridge portion on which the gate electrode is located;
a first extension portion extending from the main ridge portion toward the source opening; and
a second extension portion extending from the main ridge portion toward the drain opening.

15. The nitride semiconductor device according to claim 14, wherein
the sub gate portion includes:
a sub ridge portion formed continuously with the main ridge portion, the gate electrode being disposed on the sub ridge portion;
a third extension portion extending from the sub ridge portion toward the source opening; and
a fourth extension portion extending from the sub ridge portion toward the drain opening, and
the protrusion includes:
a protruding ridge portion protruding from the sub ridge portion toward the drain opening in the first direction; and
a fifth extension portion extending from the protruding ridge portion in conformance with a shape of the protruding ridge portion in plan view, and
the third extension portion is formed continuously with the first extension portion,
the fourth extension portion is formed continuously with the second extension portion, and
the fifth extension portion is formed continuously with the fourth extension portion.

16. The nitride semiconductor device according to claim 1, wherein
the electron supply layer is an AlₓGa₁₋ₓN layer, where 0.1<x<0.3, and
the acceptor impurity contains at least one of Mg and Zn.
